(19) United States
(12) Patent Application Publication
(10) Pub. No.: US 2024/0429865 A1
(43) Pub. Date: Dec. 26, 2024

(54) TECHNIQUES FOR RESONANT ROTARY CLOCKING FOR DIE-TO-DIE COMMUNICATION

(71) Applicant: Intel Corporation, Santa Clara, CA (US)

(72) Inventors: Jainaveen SUNDARAM PRIYA, Hillsboro, OR (US); Vinayak HONKOTE, Bangalore (IN); Ragh KUTTAPPA, Portland, OR (US); Satish YADA, Bangalore (IN); Tanay KARNIK, Portland, OR (US); Dileep J. KURIAN, Portland, OR (US)

(21) Appl. No.: 18/821,887

(22) Filed: Aug. 30, 2024

Related U.S. Application Data
(63) Continuation of application No. PCT/US2022/022658, filed on Mar. 30, 2022.

(51) Int. Cl. H03B 9/08; H01L 25/065

(52) U.S. Cl. CPC H03B 9/08; H01L 25/0652

(57) ABSTRACT

Various embodiments provide apparatuses, systems, and methods for resonant rotary clocking for die-to-die (D2D) communication in a multi-die system. A base die may include a resonant ring structure to form a plurality of rotary traveling wave oscillators (RTWOs) coupled to one another in a rotary oscillator array (ROA). The ROA may provide synchronized clock signals at deterministic phase points that are tapped from the resonant ring structure. Multiple dies may be coupled to the base die and may receive the tapped clock signals from respective tap points. The clock signals may be used for die-to-die communication and/or other purposes. Other embodiments may be described and claimed.

### CROSS-REFERENCE TO RELATED APPLICATIONS

This application is a continuation of International Application No. PCT/US2022/022658, filed Mar. 30, 2022, which is hereby incorporated by reference.

### TECHNICAL FIELD

Embodiments of the present invention relate generally to the technical field of electronic circuits, and more particularly to resonant rotary clocking in electronic circuits.

### BACKGROUND ART

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure. Unless otherwise indicated herein, the approaches described in this section are not prior art to the claims in the present disclosure and are not admitted to be prior art by inclusion in this section.

The silicon industry is moving towards die-disintegration and chiplet-based systems in which smaller heterogeneous dies are integrated on a single substrate, through which superior functionality and enhanced operating characteristics can be obtained. Designing a robust, high-speed, low-skew, low-jitter, and low-power clock across such chiplet based systems is extremely challenging. The traditional globally asynchronous locally synchronous (GALS) solution has multiple design overhead and verification challenges that have distanced designers from asynchronous solutions in general. However, enabling clock synchronization for a chiplet based systems (across multiple dies) is extremely difficult and remains a key challenge in multi-die systems.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example and not by way of limitation in the figures of the accompanying drawings.

FIG. 1A illustrates a ring structure for a rotary traveling wave oscillator (RTWO), in accordance with various embodiments.

FIG. 1B illustrates a rotary oscillator array (ROA) including a plurality of ring structures coupled to one another, in accordance with various embodiments.

FIG. 2A illustrates a multi-die system including a plurality of dies (e.g., chiplets) coupled to a base die, wherein the base die includes resonant rings of a ROA, in accordance with various embodiments. FIG. 2B illustrates a first example implementation that includes an active base die, wherein the inverters are implemented in the base die. FIG. 2C illustrates a second example implementation that includes a passive base die, wherein the inverters are implemented in the chiplets and coupled to the rotary rings (e.g., via micro-bumps).

FIG. 3A illustrates a multi-die system (e.g., system-in-package (SiP)) with resonant RTWO rings in a base die, in accordance with various embodiments.

FIG. 3B illustrates example D2D IO circuitry of first and second dies in a multi-die system, in accordance with various embodiments.

FIG. 4 illustrates an example of a rotary ring structure and associated tap points across a first die and a second die for a scheme in which the clock signal is tapped off at equal phase points, in accordance with various embodiments.

FIG. 5 illustrates example waveforms associated with die-to-die communications with resonant clocks having similar phase points, in accordance with various embodiments.

FIG. 6 illustrates an example of a rotary ring structure and associated tap points across a first die and a second die for a multi-phase tap-off scheme in accordance with various embodiments.

FIG. 7 shows resonant clock signals with different phases to illustrate a transmission window for the multi-phase tap-off scheme in accordance with various embodiments.

FIG. 8 illustrates example waveforms associated with die-to-die communications with a 3× pump ratio, in accordance with various embodiments.

FIG. 9 illustrates a multi-die system with a first die and a second die coupled to an interposer. A rectangular resonant ring is included in the interposer, across the region between the two dies, in accordance with various embodiments.

FIG. 10 illustrates an example rectangular ring structure with phase points, in accordance with various embodiments.

FIG. 11 illustrates example waveforms associated with die-to-die communications, in accordance with various embodiments.

FIG. 12 illustrates a custom rotary oscillator array (CROA) in accordance with various embodiments.

FIG. 13 illustrates an example scheme for die-to-die communication using a custom rotary oscillator, in accordance with various embodiments.

FIGS. 14, 15, 16, and 17 illustrate example schemes for die-to-die communication using a custom rotary oscillator array, in accordance with various embodiments.

FIG. 18A illustrates an example square ring rotary traveling wave oscillator structure, in accordance with various embodiments.

FIG. 18B illustrates an example square ring rotary standing wave oscillator structure, in accordance with various embodiments.

FIG. 19 illustrates an example scheme for die-to-die communication using a rotary wave oscillator that has switches to switch between a standing wave mode and a traveling wave mode, in accordance with various embodiments.

FIG. 20 illustrates an example scheme for die-to-die communication using a custom rotary wave oscillator that is switchable between a standing wave mode and a traveling wave mode, in accordance with various embodiments.

FIG. 21 illustrates a rotary oscillator array with a plurality of the rotary oscillators of FIG. 19 coupled (e.g., shorted) together, in accordance with various embodiments.

FIG. 22 illustrates an example system configured to employ the apparatuses and methods described herein, in accordance with various embodiments.

### DETAILED DESCRIPTION

Various embodiments herein provide apparatuses, systems, and methods for resonant rotary clocking for die-to-die communication, in accordance with various embodiments. For example, a multi-die system may include an interposer and two or more dies coupled to the interposer. The interposer may include a resonant rotary ring structure to form one or more resonant rotary oscillators (e.g., of a resonant rotary oscillator array). The resonant rotary oscillators may be traveling wave and/or standing wave oscillators. The dies may tap respective clock signals from the rotary ring structure and use the clock signals for die-to-die communication.

In the following detailed description, reference is made to the accompanying drawings that form a part hereof wherein like numerals designate like parts throughout, and in which is shown by way of illustration embodiments that may be practiced. It is to be understood that other embodiments may be utilized and structural or logical changes may be made without departing from the scope of the present disclosure. Therefore, the following detailed description is not to be taken in a limiting sense, and the scope of embodiments is defined by the appended claims and their equivalents.

Various operations may be described as multiple discrete actions or operations in turn, in a manner that is most helpful in understanding the claimed subject matter. However, the order of description should not be construed as to imply that these operations are necessarily order dependent. In particular, these operations may not be performed in the order of presentation. Operations described may be performed in a different order than the described embodiment. Various additional operations may be performed and/or described operations may be omitted in additional embodiments.

The terms “substantially,” “close,” “approximately,” “near,” and “about,” generally refer to being within +/−10% of a target value. Unless otherwise specified the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

For the purposes of the present disclosure, the phrases “A and/or B” and “A or B” mean (A), (B), or (A and B). For the purposes of the present disclosure, the phrase “A, B, and/or C” means (A), (B), (C), (A and B), (A and C), (B and C), or (A, B, and C).

The description may use the phrases “in an embodiment,” or “in embodiments,” which may each refer to one or more of the same or different embodiments. Furthermore, the terms “comprising,” “including,” “having,” and the like, as used with respect to embodiments of the present disclosure, are synonymous.

As used herein, the term “circuitry” may refer to, be part of, or include an Application Specific Integrated Circuit (ASIC), an electronic circuit, a processor (shared, dedicated, or group), a combinational logic circuit, and/or other suitable hardware components that provide the described functionality. As used herein, “computer-implemented method” may refer to any method executed by one or more processors, a computer system having one or more processors, a mobile device such as a smartphone (which may include one or more processors), a tablet, a laptop computer, a set-top box, a gaming console, and so forth.

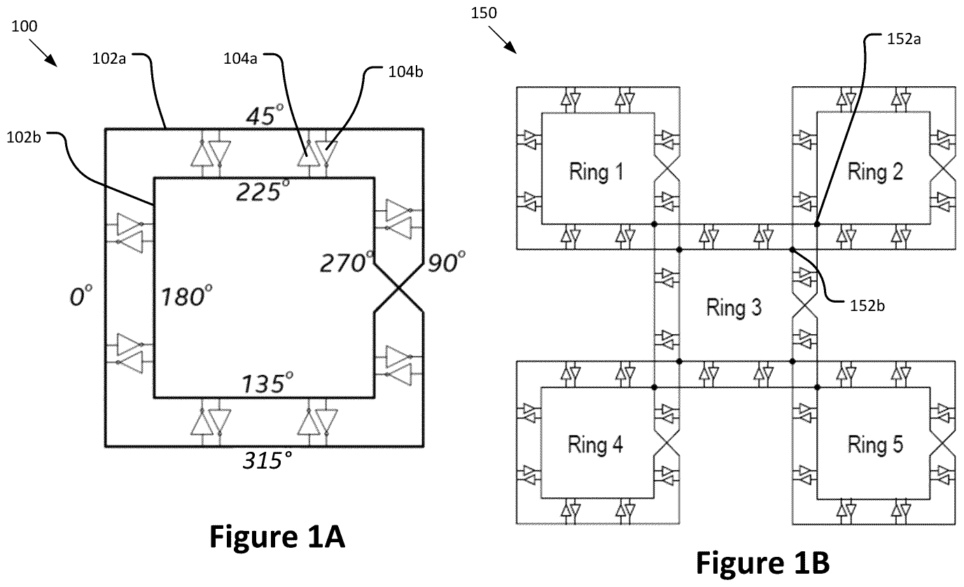

Rotary traveling wave oscillators (RTWO) may include a ring structure on which the clock signal travels as a traveling wave. Multiple RTWOs may be coupled to one another in a rotary oscillator array (ROA) to distribute the clock signal over a larger area. For example, FIG. 1A illustrates a RTWO including rotary rings 102a and 102b. The rotary rings 102a-b may be cross-coupled to one another, such that the clock signal may travel continuously along both rotary rings 102a-b. The clock signal may be tapped at different tap points on the ring structure to provide different phases of the clock signal as shown (e.g., 0°, 45°, 90°, etc.). The rotary rings 102a-b may be implemented using interconnects (ICs) and/or other suitable conductive structures for the transmission lines. The RTWO 100 may further include one or more pairs of inverters 104a-b coupled between the rotary rings 102a-b in anti-parallel fashion to power and amplify the signals adiabatically. In some embodiments, the pairs of inverters 104a-b may be complementary metal-oxide-semiconductor (CMOS) inverters, although other types of inverters/transistors may also be used. Additionally, or alternatively, the pairs of inverters 104a-b and/or may be distributed uniformly along the transmission lines.

In embodiments, the RTWO may be modeled as an inductor-capacitor (LC) oscillator, where the frequency fₒₛₑ is estimated by:

$${f}_{o s c} \approx \frac{{v}_{p}}{2 l} = \frac{1}{\sqrt{{L}_{T} {C}_{T}}} \qquad ( 1 )$$

In Equation (1), vₚ is the phase velocity and I is the length/perimeter of the ring. The 2 factor (in the denominator) arises from fact that the pulse requires two complete laps for a single cycle. Further, the total inductance and total capacitance of a rotary ring are defined by L_{T} and C_{T}, respectively. The total inductance L_{T} depends on the geometry of the rotary ring and C_{T} is the total capacitance of the ring, interconnects and devices connected to the rotary ring.

FIG. 1B illustrates an example ROA 150 that includes a plurality of RTWOs 100 coupled to one another. The RTWOs may be shorted to one another at shorting locations 152a-b. For example, the corner of the outer ring of a first RTWO (e.g., Ring 2 in FIG. 1B) may be shorted to the corner of the inner ring of a second RTWO (e.g., Ring 3 in FIG. 1B) at shorting location 152a, and the corresponding corner of the inner ring of the first RTWO may be shorted to the corresponding corner of the outer ring of the second RTWO at shorting location 152b. The shorting may enable the ROA 150 to provide a clock signal at synchronized tap points across the ROA 150. Other configurations of the RTWOs may also be used in accordance with various embodiments. Furthermore, multiple RTWOs and/or ROA structures may be coupled to one another to distribute the clock signals across a reticle area.

Various embodiments herein include techniques to use ROAs to provide clock synchronization across a multi-die system (MDS) for die-to-die (D2D) communication (e.g., D2D input-output (IO). The MDS may include, for example, a System-In-Package (SiP). The MDS may include multiple dies coupled to a common base die (e.g., interposer) and/or otherwise integrated into a same package. The dies may include heterogenous dies of different types and/or capabilities. Additionally, or alternatively, the dies may include multiple similar/same dies. For example, the dies may include one or more processor dies, memory dies, graphics processor dies, input-output (IO) dies, power management dies, and/or other suitable types of die.

Aspects of various embodiments herein may include, but are not limited to:
Use of the resonant clock as a common IO clock for D2D IO communication, e.g., by tapping the clock signal at deterministic phase points. This may eliminate the need for IO clocking infrastructure found in prior designs, such as phase-locked loops (PLLs), drivers for strobe forwarding, and delay-locked loops (DLLs). In some embodiments, the clock signal may be tapped at the same phase point at the transmit and receive sides. In other embodiments, the clock signal may be tapped at a different phase point at the receive side than the transmit side. For example, the clock signal tapped at the receive side may be 45-135 degrees ahead in phase compared with the clock signal tapped at the transmit side. In embodiments, the phase lead of the receive side may improve setup margin and/or enable faster operation.
The overall D2D circuit design is simplified, e.g., by replacing strobe generation/recovery circuitry (e.g., PLLs, strobe drivers, DLLs) with inverter pairs, while also reducing area and power.
A rectangular resonant ring may be included on the interposer, with longer edges overlapping the periphery of the top dies that are coupled to the interposer.
Custom rotary ring structures for D2D communication. The custom rotary ring structures may be implemented using an active and/or passive interposer.
The ROA for D2D IO may be a traveling wave oscillator and/or a standing wave oscillator. Some embodiments may include a multi-mode oscillator circuit that is switchable between a traveling wave mode and a standing wave mode.
These and other aspects of various embodiments are described further below.

### Implementation Using Passive or Active Interposer

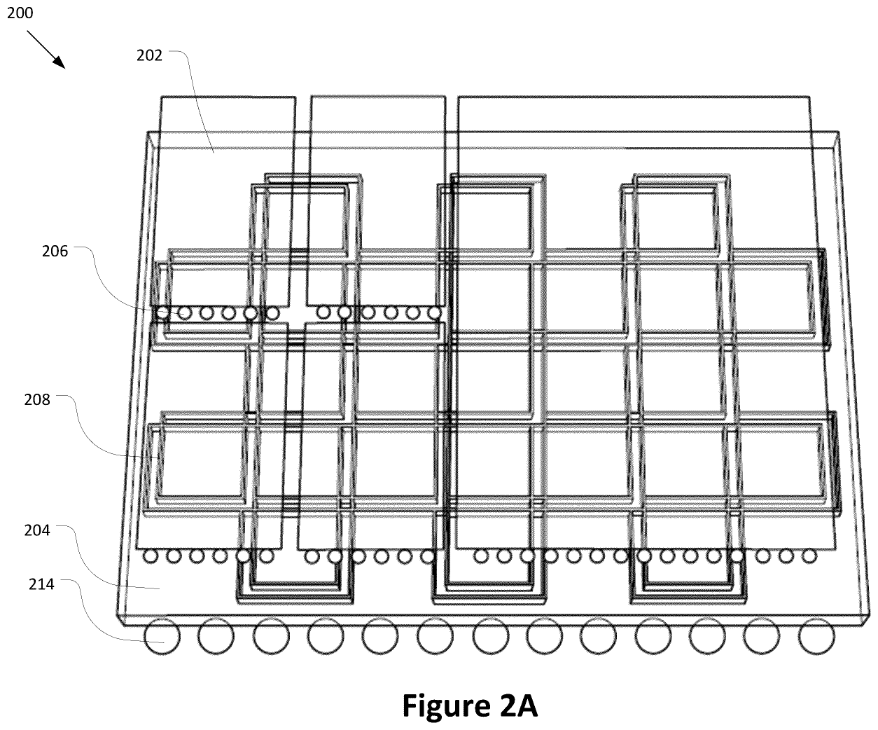

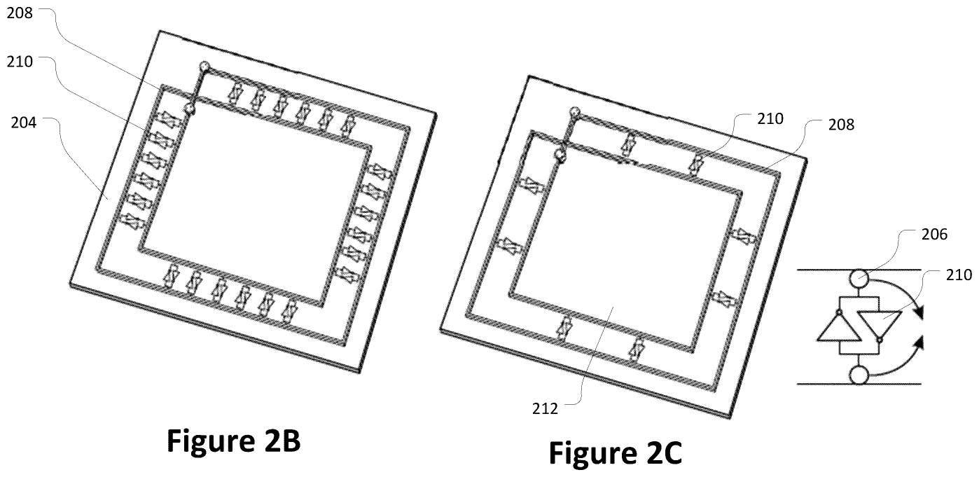

In various embodiments, the resonant clocking circuit may be implemented in a multi-die system using a passive or active interposer (also referred to as a base die). FIG. 2 illustrates an example multi-die system 200 that includes a plurality of dies (e.g., chiplets) 202 coupled to a base die 204 (e.g., via μ-bumps 206 and/or another suitable mechanism). The base die 204 may include resonant rings 208 formed therein, e.g., in one or more metal layers. The clock signals on the resonant rings 208 may be tapped (e.g., from respective tap points) and provided to the dies 202 through the μ-bumps, e.g., as reference signals for synchronization. Due to the nature of ROAs, multiple tap points exist on the resonant ring structure which we may be used for synchronization, as further discussed herein.

In some embodiments, the multi-die system 200 may include an active base die 204. For example, FIG. 2B illustrates an active base die 204 that includes inverter pairs 210 implemented in the base die 204 and coupled between the inner and outer rings of the resonant rings 208. FIG. 2C illustrates an example of a passive base die 204, in which the inverter pairs 210 are implemented in another die 212. The inverter pairs 210 may be coupled to the resonant rings 208 via μ-bumps and/or another suitable mechanism. In some embodiments, the die 212 may correspond to the dies 202 of the multi-die system 200 (e.g., each die 202 may include inverter pairs that are coupled to respective resonant rings 208 of the base die 204).

The resonant rings in the base die 204 may enable the dies 202 to tap synchronized clock signals with deterministic phase points. In some embodiments, the base die 204 may include bumps 214 coupled to a lower surface of the base die 204, e.g., to mount the multi-die system on a motherboard or another circuit structure. The bumps 214 may be larger (e.g., C4 bumps) than the μ-bumps 206 used to couple the die 202 to the base die 204 in some embodiments.

Silicon interposer-based systems allow for integration of heterogeneous dies capitalizing on the yield and cost benefits. The footprint on the interposer is important because passive interposers demonstrate superior yield with cost reduction through die partitioning, while active interposers demonstrate superior performance while trading-off with cost/yield. Embodiments herein enable the resonant clocking circuit to be used with either a passive or active interposer.

### Alternate Phase Reception for Die-to-Die (D2D) Input-Output (IO) Circuits

In various embodiments, the synchronized resonant clock signal described herein may be used for die-to-die (D2D) communication (also referred to as D2D input-output (IO)), e.g., in a multi-die system. In some embodiments, the D2D communication may use alternate phase tap-off points at the transmit (Tx) side and receive (Rx) side (e.g., at the Tx side serializer and Rx side deserializer), as described further below.

The figures of merit for D2D IO include the bandwidth (BW)/mm and energy/bit. In prior implementations, D2D IO typically includes a phase-locked loop (PLL) on the Tx side to generate high speed edges, which are used to serialize data and a strobe bundle (e.g., for higher BW/mm). This bundle is forwarded to the receiver, where it is deserialized and transitioned to the Rx die clock domain (e.g., using a clock-domain-crossing (CDC) first-in/first-out (FIFO)).

This IO clocking infrastructure (e.g., PLLs on the Tx side, drivers for strobe forwarding, and delay-locked loops (DLLs) on the Rx side) contributes to a dominant chunk of overall energy/bit of the D2D IO and occupies significant area footprint. To improve energy/bit, schemes typically adopt approaches such as voltage scaling or balancing the ratio of data lines/strobe.

In accordance with various embodiments herein, a rotary oscillator array may be laid out across the base die (e.g., interposer), providing deterministic phase points across the multi-die system (e.g., SiP). In embodiments, this resonant clock may be used as the common IO clock for D2D communication. For example, the resonant clock signal may be tapped at deterministic phase points at the Tx and Rx side of D2D IO within respective dies (e.g., chiplets). The use of the synchronized resonant clock signal may avoid the need for Tx-side PLLs, strobe forwarding, and Rx-side DLLs of prior techniques, thereby reducing the overall energy/bit and/or area footprint of D2D IO.

In some embodiments, alternate phase tap-off points may be used at the Tx side and Rx side for D2D IO. For example, on the Tx side, data may be serialized using Phase-A of the resonant clock signal. On the Rx side, data may be captured using Phase-B of the resonant clock. The captured data may be de-serialized and passed to CDC FIFO. In one example, Phase-B leads Phase-A in phase, e.g., by 45-135 degrees. The phase lead between Phase-B and Phase-A may be used to improve setup margin of the IO scheme (e.g., by 16-37%), thereby enabling faster operation.

The D2D IO scheme described herein may be complementary to voltage scaling techniques. Accordingly, voltage scaling may also be used in some embodiments. Additionally, the lack of strobe forward lines means that more data lines can be included in the same circuit area.

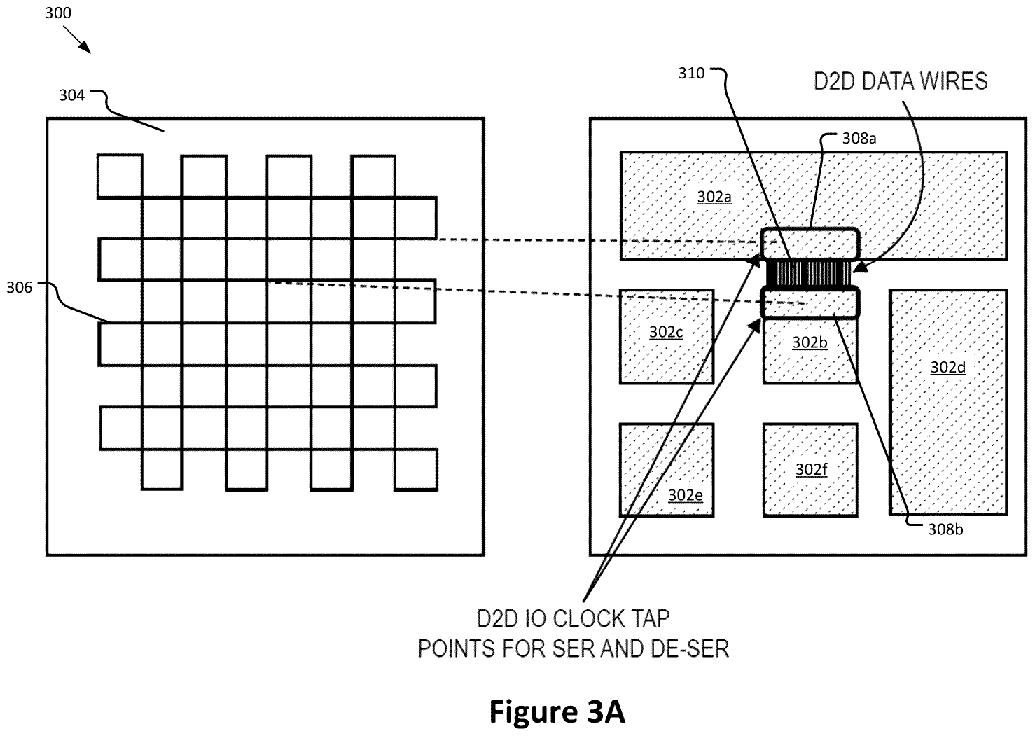

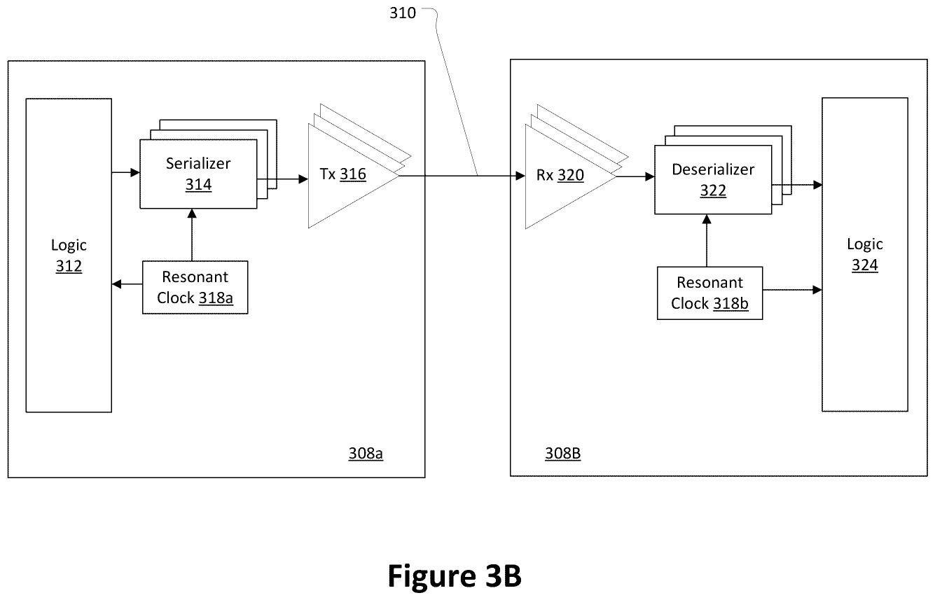

FIG. 3A illustrates a multi-die system 300 (e.g., SiP) with a resonant oscillator array used for D2D communication, in accordance with various embodiments. The multi-die system 300 includes a plurality of dies (e.g., chiplets) 302a-f coupled to a base die (e.g., interposer) 304. The base die 304 may include resonant rings 306 to form a ROA as described herein. The left side of FIG. 3A illustrates the base die 304 without dies 302a-f to illustrate the resonant rings 306. In some embodiments, the individual dies 302a-f may include one or more cross-coupled inverter pairs to excite the resonant rings 306 of the base die. Alternatively, or additionally, the base die 304 may be an active die that includes cross-coupled inverter pairs to excite the resonant rings 306.

The dies 302a-f may further include respective IO circuitry (e.g., PHY circuitry) to communicate with other dies of the dies 302a-f. For example, FIG. 3A illustrates an IO circuitry 308a of die 302a and IO circuitry 308b of die 302b. Although not shown in FIG. 3, the dies 302a-b may also include one or more IO circuitries to communicate with one or more of the other dies 302c-f. Additionally, or alternatively, the other dies 302c-f may include IO circuitries to communicate with one or more of the other dies 302a-f.

In embodiments, the IO circuitries 308a-b may communicate (e.g., transmit and/or receive data) with one another via a bus 310. The bus 310 may include one or more communication paths (e.g., data wires). For example, the bus 310 may include a plurality of communication paths for parallel communication. In various embodiments, the resonant clock signals described herein may be used at the dies 302a-b to serialize data (e.g., at the Tx side) and/or de-serialize data (e.g., at the Rx side) that is transmitted on the bus 310.

For example, FIG. 3B illustrates an example of IO circuitries 308a and 308b in accordance with some embodiments. As illustrated, the IO circuitry 308a may include logic 312, one or more serializers 314 coupled to the logic, and one or more Tx drivers 316 coupled to the serializers. The logic 312 may provide data to the one or more serializers 314. The one or more serializers 314 may tap a resonant clock 318a from a resonant clock circuitry (e.g., resonant rings 306 of FIG. 3A) and serialize the data based on the tapped clock. The one or more serializers 314 may provide the serialized data to respective Tx drivers 316 for transmission over respective communication paths of bus 310.

The IO circuitry 308b may include one or more Rx drivers 320 coupled to the bus 310, one or more deserializers 322 coupled to respective Rx drivers 320, and logic 324 coupled to the one or more deserializers 322. The one or more Rx drivers 320 may receive the serialized data and pass the serialized data to respective deserializers 322. The deserializers 322 may tap a resonant clock 318b from a resonant clock circuitry (e.g., resonant rings 306 of FIG. 3A) and deserialize the data based on the tapped clock. The deserializers 322 may pass the deserialized data to the logic 324 for further processing.

The IO circuitry 308a-b is merely one example, and other configurations of IO circuitry may be used with resonant clock signals in accordance with various embodiments herein. For example, some embodiments may not use serializers and deserializers. In one such example, the transmitter may send data directly based on a Tx clock. The Tx clock may be the resonant clock signal or a frequency-adjusted version of the resonant clock signal. For example, the resonant clock signal may be used as a global clock for the multi-die system, and the IO circuitries may use transmit/receive clocks that have a lower frequency than the global clock.

In some embodiments, the resonant clock signal may be tapped off at equal phase points at the Tx side and Rx side. Accordingly, the entire period of the clock signal may be used as the D2D transmission window (e.g., flight time+setup margin).

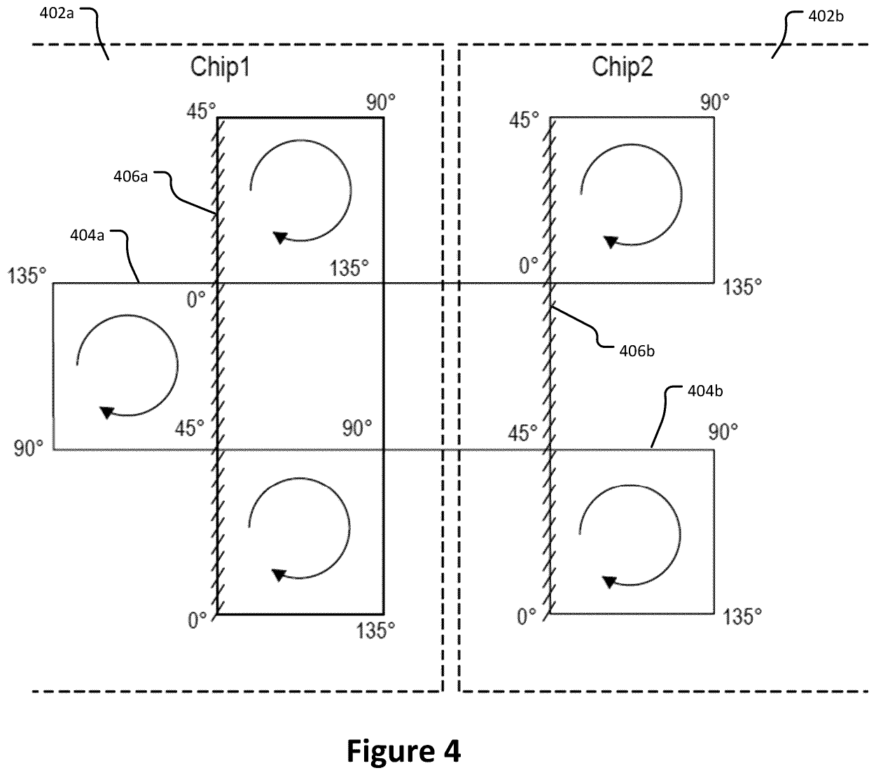

FIG. 4 schematically illustrates an example of the rotary ring structure and tap points for a communication scheme that uses equal phase points. As shown, a first die 402a and a second die 402b may each include a resonant ring structure 404a-b. FIG. 4 further shows the phase of the resonant clock signal at various points on the resonant ring structure 404a-b. In embodiments, first and second dies 402a-b may tap the resonant clock signal at corresponding tap points 406a-b that correspond to the same phase points. For example, the first and second dies 402a-b may include a serializer and/or deserializer for communications between the first and second dies 402a-b and may use the tapped clock signal to serialize and/or deserialize the data. By tapping off similar phase points and using that as IO clock for the nearest serializer/de-serializer, one high-speed clock period may be used as the D2D transmission window.

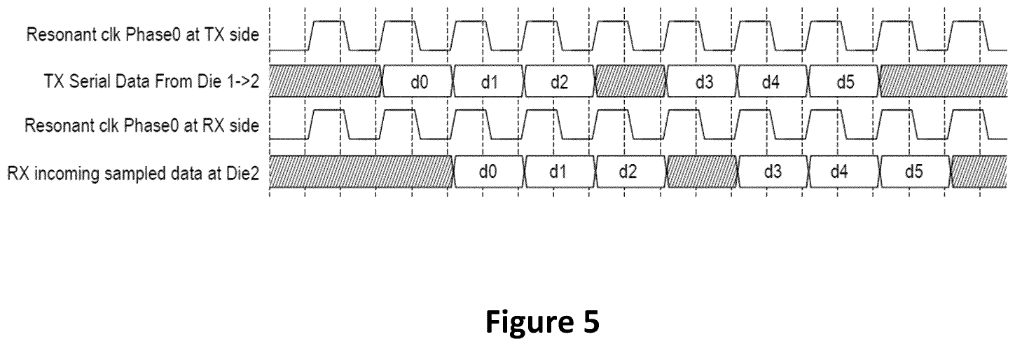

For example, FIG. 5 illustrates an example of the resonant clocks with similar phase points, the Tx serial data from Die 1 to Die 2, and the Rx incoming sampled data at Die 2.

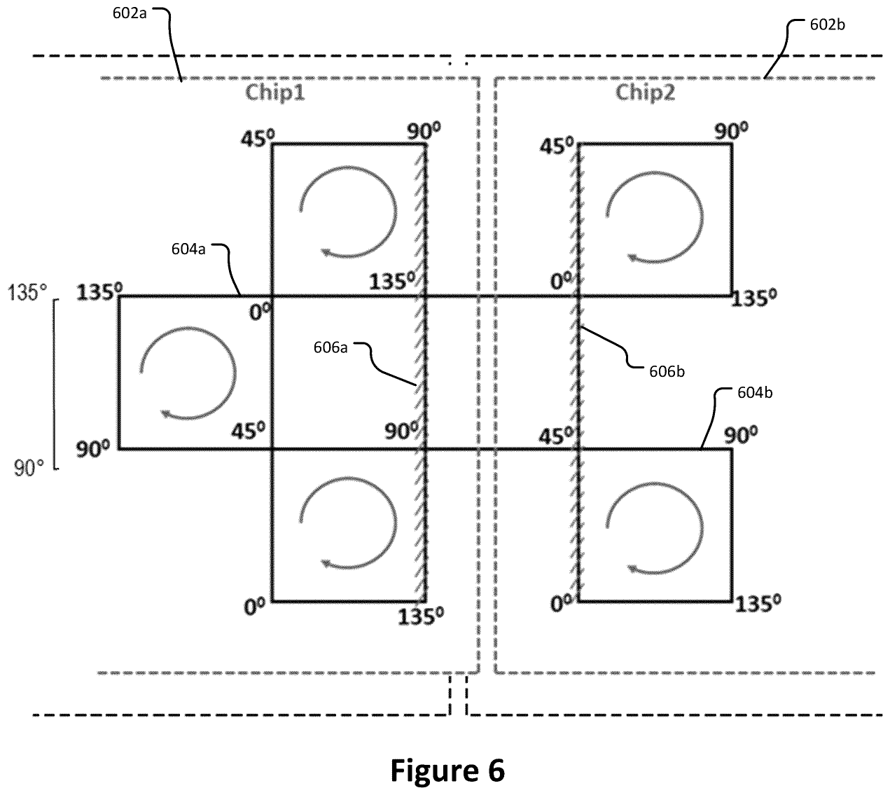

In other embodiments, a multi-phase tap-off scheme may be used for D2D IO. FIG. 6 illustrates an example of the rotary ring structures 604a-b and tap points 606a-b across a first die 602a and a second die 602b for a multi-phase tap-off scheme. Instead of tapping of similar phase points, as discussed above, alternate phase points may be used for tap points 606a-b. This approach may decrease the distance the high speed clock gets shipped and/or increase the transmission window of the D2D IO.

In various embodiments, the tapped clock signal used at the Rx side may lead in phase the tapped clock signal used at the Tx side, e.g., by 45-135 degrees. For example, consider the second die 602b transmitting the first die 602a in FIG. 6. The resonant clock phase variation on the Tx side at tap points 606b is between 0-45 degrees, while on the Rx side the phase variation at tap points 606a is 135-90 degrees.

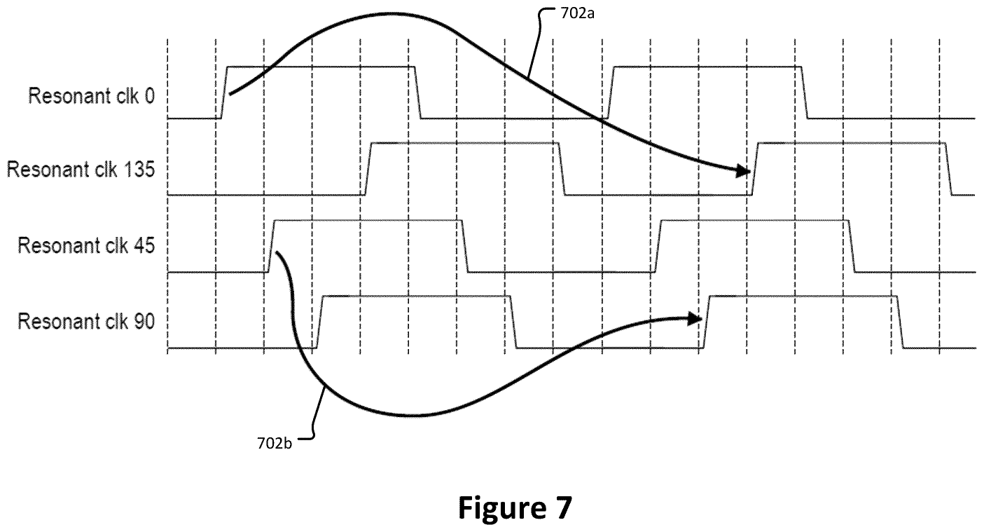

In various embodiments, transmitting between any two phase points on the same line (e.g., corresponding tap points 606a-b, increases the transmission window, e.g., by ⅛^{th} to ⅜^{th} of overall period. FIG. 7 illustrates an example of transmission windows 702a-b for a 135 degree phase difference and a 45 degree phase difference, respectively. Additionally, the overall distance the clock signals are shipped within a chiplet may decrease to L^{ien} (from 2*L^{ien} in the case of using same phase points).

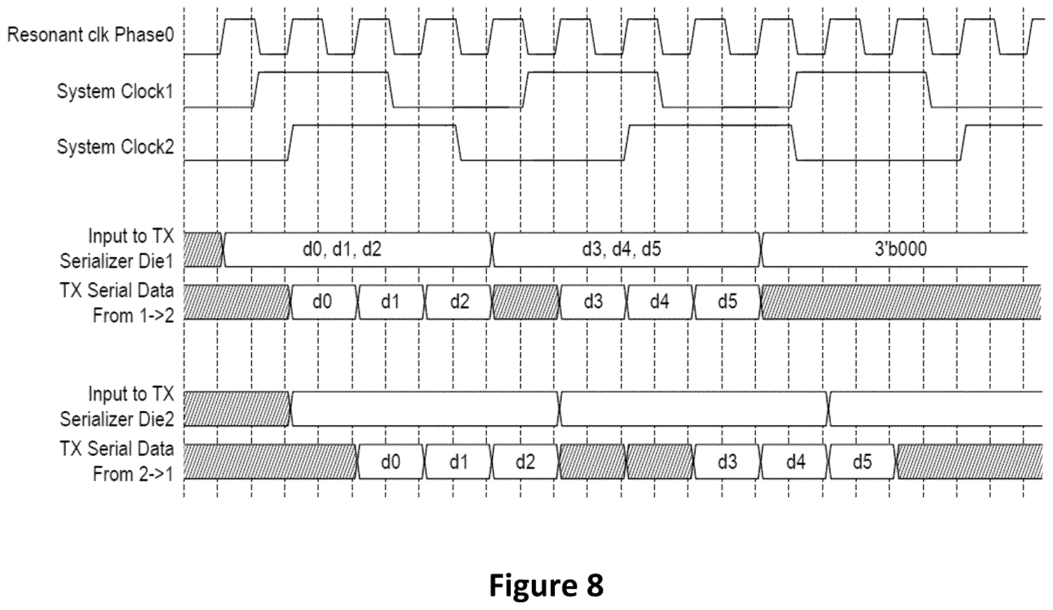

FIG. 8 illustrates various waveforms to show an example of the Tx side transmission from one die to another for a 3X pump ratio. For example, FIG. 8 illustrates a resonant clock signal with phase 0, a first system clock (System Clock 1), and a second system clock (System Clock 2). The first and second system clocks may have a period that is three times the period of the resonant clock signal. Additionally, the second system clock has a different phase than the first system clock (e.g., by ½ the period of the resonant clock signal, corresponding to a 60 degree difference with the first system clock). FIG. 8 further illustrates an input signal to a Tx serializer on Die 1 and Tx serial data transmitted from Die 1 to Die 2. Furthermore, FIG. 8 illustrates an input signal to a Tx serializer on Die 2 and Tx serial data transmitted Die 2 to Die 1.

In some embodiments, the D2D IO traffic may be asynchronous between the two dies (as the timing is determined by the phase relationship between Tx side clock and IO clock). On the Rx side, the data may be de-serialized and handed off to the CDC FIFO.

### Rectangular Resonant Ring Across Chiplets

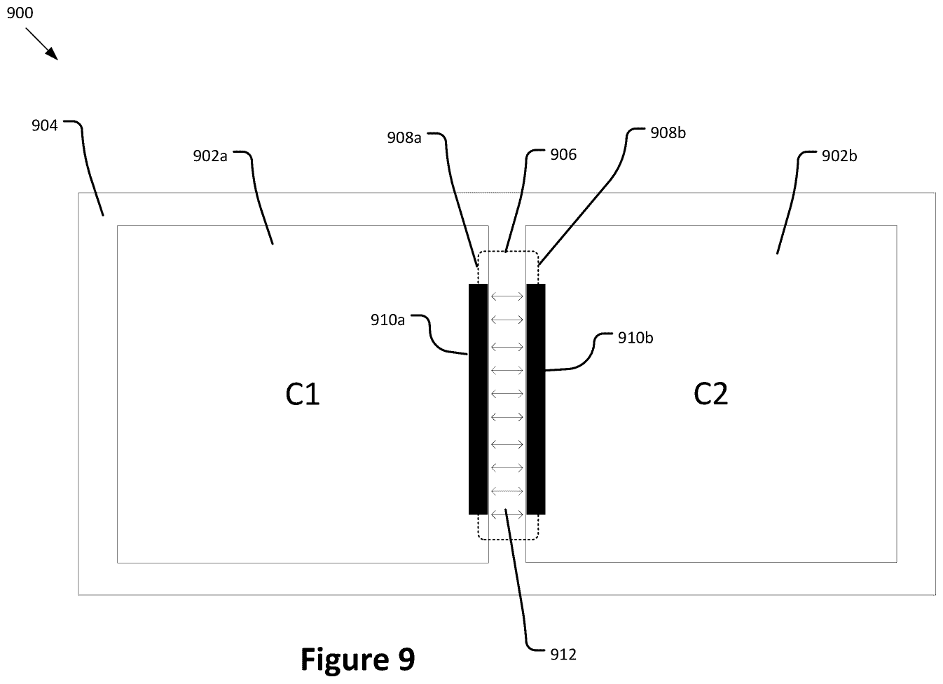

FIG. 9 illustrates a multi-die system 900 including a first die 902a (C1) and a second die 902b (C2) coupled to an interposer 904. The multi-die system 900 may be a heterogeneous system in some embodiments. The dies 902a and 902b may include logic and/or memory.

In embodiments, the interposer 904 may include a resonant ring 906 disposed across the region adjoining the dies 902a and 902b. For example, a first long edge 908a of the resonant ring 906 may be partially or completely under the first die 902a and a second long edge 908b of the resonant ring 906 may be partially or completely under the second die 902b.

The dies 902a-b may include respective D2D PHY circuitry 910a-b. In some embodiments, the D2D PHY circuitry 910a-b may be above the respective long edge 908a-b of the resonant ring 906 The D2D PHY circuitry 910a-b may include data serializers and/or de-serializers for data transmission. In some embodiments, the D2D PHY circuitry 910a-b may further include inverter pairs to excite the resonant ring 906. The resonant ring 906 provides a common strobe, with a deterministic phase at any tap off point. This strobe may be tapped off by the D2D PHY circuitry 910a-b from the nearest points both at the serializer and the de-serializer to transition between parallel data to serial bit stream.

For example, at die 902a, the resonant ring 906 may be tapped to pull the high-speed IO clock, which is used to serialize data and transmit the serialized data to die 902b (e.g., via D2D interconnects 912). At die 902a, a local IO clock copy may be tapped off the nearest point to the resonant ring and used to deserialize data. The deserialized data may be passed to a clock-domain crossing (CDC) first-in, first-out (FIFO) circuit.

The deterministic phase difference between tap off points at the dies 902a-b (e.g., as described in the next section and elsewhere herein) ensures a reliable setup/hold margin for the data going across the dies 902a-b.

### Data Transmission Using Strobe Generated by Rectangular Ring

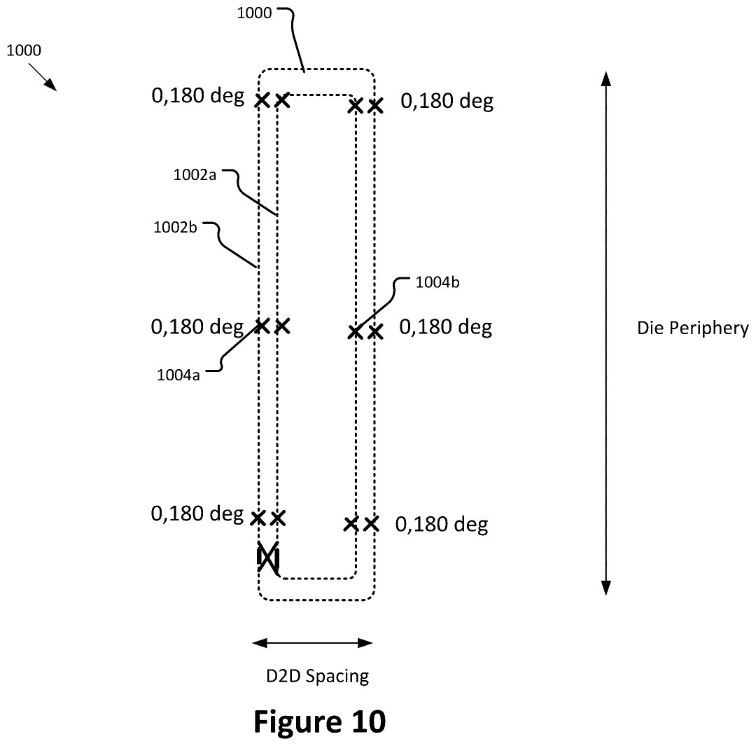

Typically, the edge of a die is much longer than the die to die spacing. FIG. 10 illustrates an example resonant ring 1000 with phase points at different tap points of the resonant ring 1000 indicated. The comma separates the clock phases for the respective tracks making up the ring 1000 (e.g., inner ring 1002a and outer ring 1002b). For sake of clarity, inverter pairs (which excite the ring 1000) are not shown in FIG. 10.

In embodiments herein, an alternate track tap out scheme may be used. For example, if a signal is transmitted using the clock derived from the outer ring 1002b, it is received using the clock derived from the inner ring 1002a.

As an example, consider the IO located close to the middle of the resonant ring 1000. At a first die (e.g., the die 902a of FIG. 9), the clock from the outer ring 1002b may be tapped (e.g., at tap point 1004a) and used to serialize data. The tapped clock may have a phase of 45 degrees, as shown. At a second die (e.g., the die 902b of FIG. 9), the clock from the inner ring 1002a may be tapped (e.g., at tap point 1004b) and used to de-serialize the data. This tapped clock may have a phase of 315 degrees, as shown. This gives us a total window of 270 degrees for transmission. For an 8G resonant ring, this translates to 93 ps of transmission window. In some embodiments, the transmission window varies from P (e.g., at the bottom part of ring 1000) to half of P (e.g., at the top part of ring 1000), where P refers to period of the IO resonant clock.

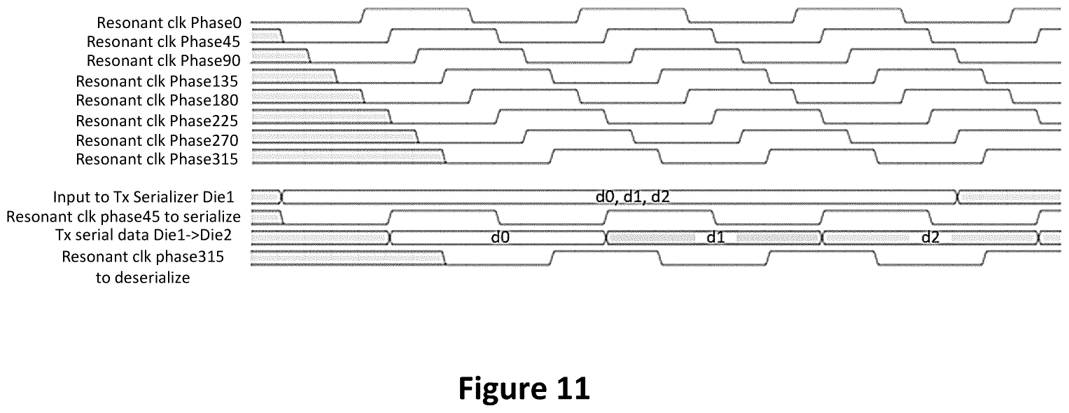

FIG. 11 depicts several example waveforms to illustrate the alternate track tap out scheme in accordance with various embodiments. For example, FIG. 11 illustrates the resonant clock signal at various phase points. Additionally, FIG. 11 illustrates the input to the Tx serializer at the first die, the resonant clock used to serialize the data at the first die, the serial data transmitted from the first die to the second die, and the resonant clock signal used to deserialize the data at the second die.

Serializers in the first die use the nearest resonant ring tap off point to transmit data. In FIG. 11, phase 45 is shown as an example, used to serialize data at the TX side and transmit to the RX side. At the RX side, the same tapping point outputs a 315 degree phase clock, which is used to de-serialize data.

### D2D IO Using Custom Rotary Ring Structures

Various embodiments herein include custom rotary ring structures for a rotary oscillator array (e.g., for D2D IO). The custom rotary rings may include on-chip interconnects and inverter pairs that are terminated mobiusly (as described herein) to generate a resonating clock signal with 50% duty cycle. The custom rings and/or custom rotary oscillator arrays may be used for tapping clock signals for D2D IO. The resonant rings oscillate to generate an IO clock with deterministic phase points across dies. The IO clock may be used to serialize and de-serialize data.

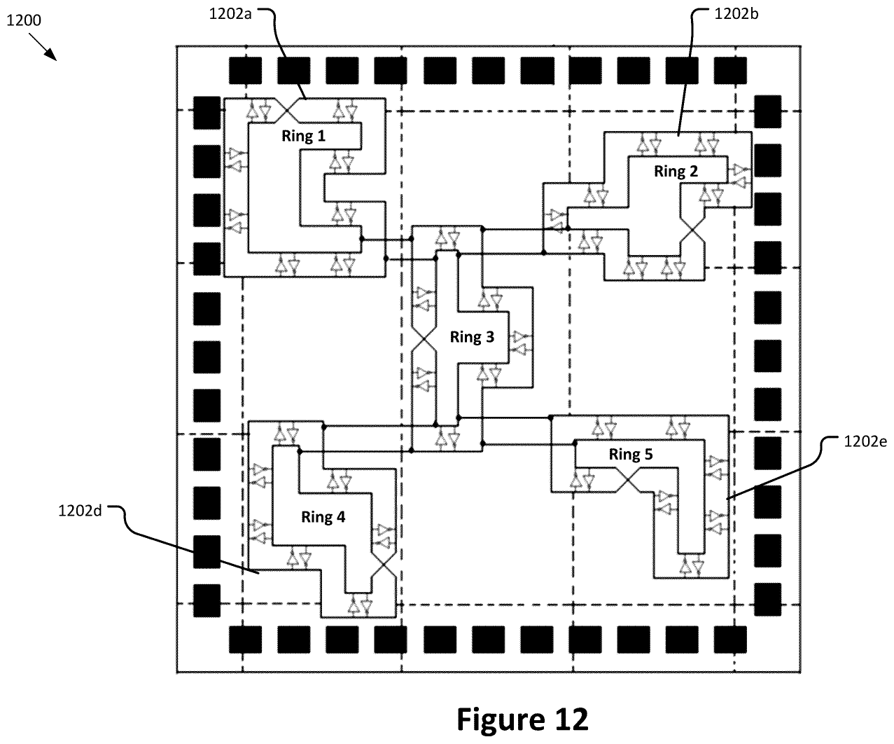

For example, FIG. 12 illustrates an example custom rotary oscillator array (CROA) 1200 in accordance with various embodiments. The CROA includes a plurality of custom rotary oscillators 1202a-e coupled (e.g., shorted) to one another. The custom rotary oscillators 1202a-e are merely examples of various embodiments. The custom rotary oscillators 1202a-e may include any suitable shape, e.g., to provide tap points at desired locations and/or clock signals with a desired phase at one or more locations. The custom rotary oscillators 1202a-e may have a rectilinear shape that is non-rectangular. In some embodiments, one or more custom rotary oscillators 1202a-c may be combined with one or more regular (e.g., rectangular) rotary oscillators in a rotary oscillator array.

As with the regular resonant rings, the custom resonant rings may be implemented in the interposer (e.g., silicon interposer). In some embodiments, the inverter pairs to excite the resonant ring may be implemented in the dies that are coupled to the interposer and/or in the interposer itself. The inverter pairs may replace conventional strobe infrastructure (e.g., PLLs, strobe drivers, DLLs) of prior IO circuits.

The techniques described herein may enable the use of custom rotary rings that may be employed for D2D IOs in multi-die systems (e.g., heterogeneous multi-die systems). The custom rings may be coupled to one another to form custom rotary oscillator arrays to distribute the required clocks across a large area (e.g., the whole reticle). Embodiments may include chiplet-aware resonant array implementation to identify the required clock tap-points for D2D IOs. Accordingly, the shape of the resonant rings may be designed to provide tap points at desired locations to the top dies coupled to the interposer. The traveling wave scheme provides deterministic delay, which may facilitate use in D2D IO circuits. This scheme may enable the use of either the same phase points on multiple custom rings and/or different phase points with deterministic delays on the custom rings for D2D IO.

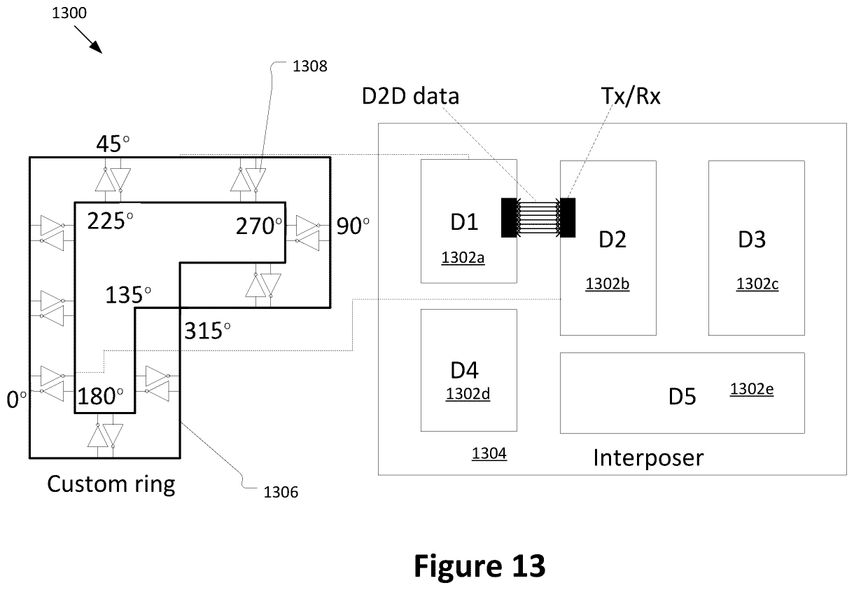

With the resonant traveling wave scheme, it is possible to tap the clock signals from different points of the custom ring and provide them as inputs to the chiplets. As the delay/phase at the tapping points are deterministic, the difference in the phase/delay is used as the transmission window. FIG. 13 illustrates an example multi-die system 1300 with dies D1-D5 1302a-e coupled to an interposer 1304. The interposer 1304 may include one or more custom rotary rings 1306 (e.g., coupled in a rotary oscillator array). Each die D1-D5 may incorporate one or more cross-coupled inverter pairs 1308 to excite the resonant rings 1306. The clock signals from the custom rotary ring 1306 may be provided to the dies D1-D5. For example, representative tap points are illustrated in FIG. 13 for dies D1 and D2. This principle may be extended to tap clocks from multiple points on the custom ring with deterministic delays. At any point on the ring, the clock signal delay ‘t’, the clock signal phase ‘θ’ and the clock period ‘T’ are correlated through:

$$\frac{θ}{360} = \frac{t}{T} \qquad ( 2 )$$

For instance, for a 4 GHz resonant ring in FIG. 13, for die D1—a clock may be tapped from a point on the ring where θ-60°. For D2, the clock may be tapped from the same structure but from the inner ring where θ=180°. This provides a window of 120°. This translates to the transmission window of 82 ps (e.g., using Equation (2)). Note that the clocks to different dies may additionally or alternatively be tapped from other/different points on the ring, e.g., depending on requirements.

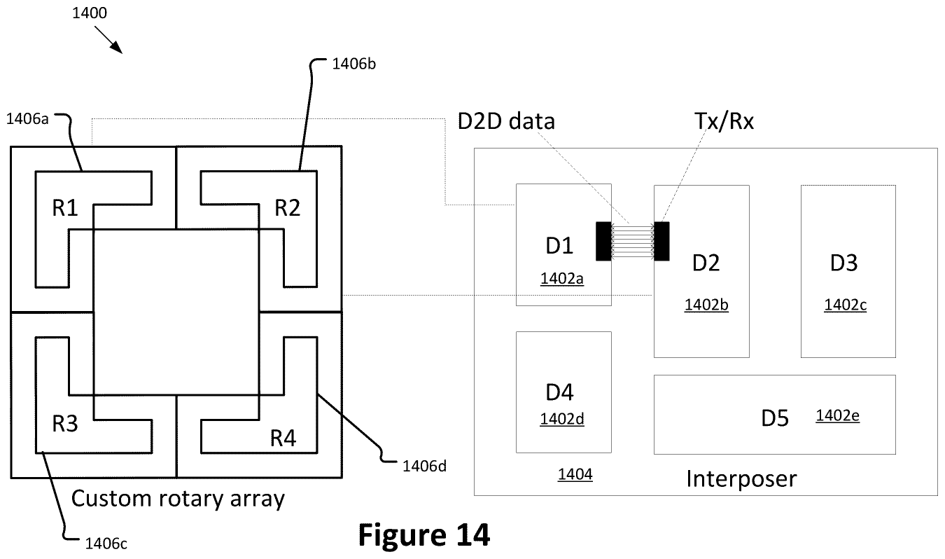

Other schemes for D2D IO using an array of custom rings may be used in accordance with various embodiments, For example, FIG. 14 illustrates a multi-die system 1400 with dies 1402a-c on an interposer 1404. The interposer 1404 may include multiple ring structures 1406a-d coupled in an array (e.g., of 4 ring structures 1406a-d). The ring structures 1406a-d may correspond to the rotary ring 1306 of FIG. 13. As there is at-least 1 same phase point on each ring structure 1406a-d, the clocks for different dies 1402a-e may be tapped from these same-phase points. Further, depending on the architecture and placement of the dies 1402a-e, the ring structures 1406a-e may be laid out to enable a favorable transmit/receive window for D2D IO. Thus, a chiplet-placement aware resonant rotary clocking scheme may be implemented on the interposer 1404 for efficient D2D IO.

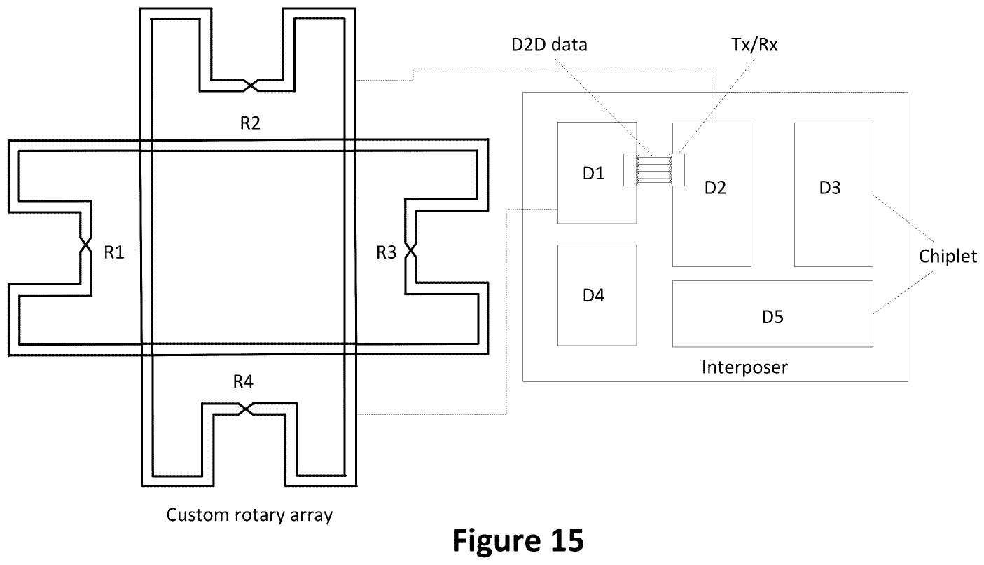

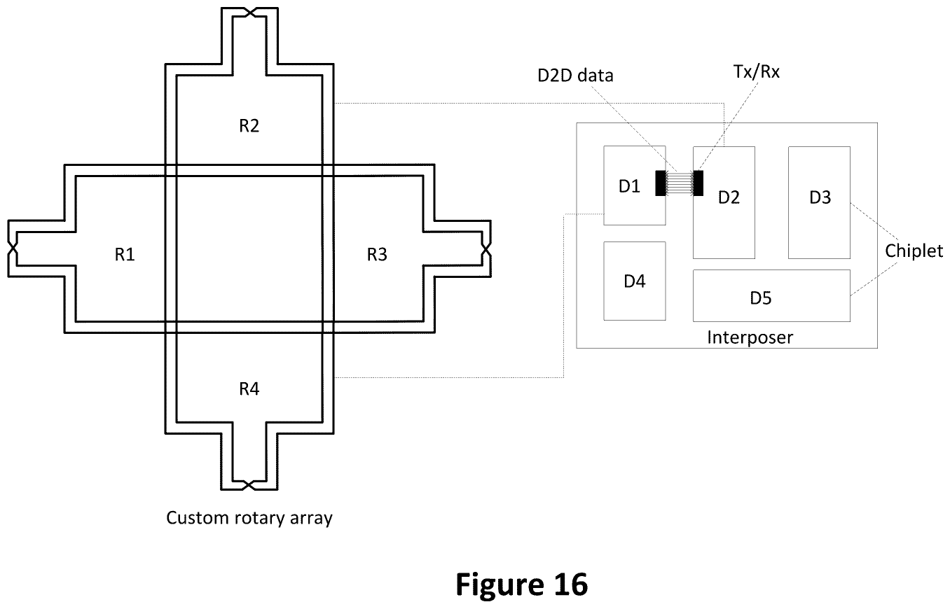

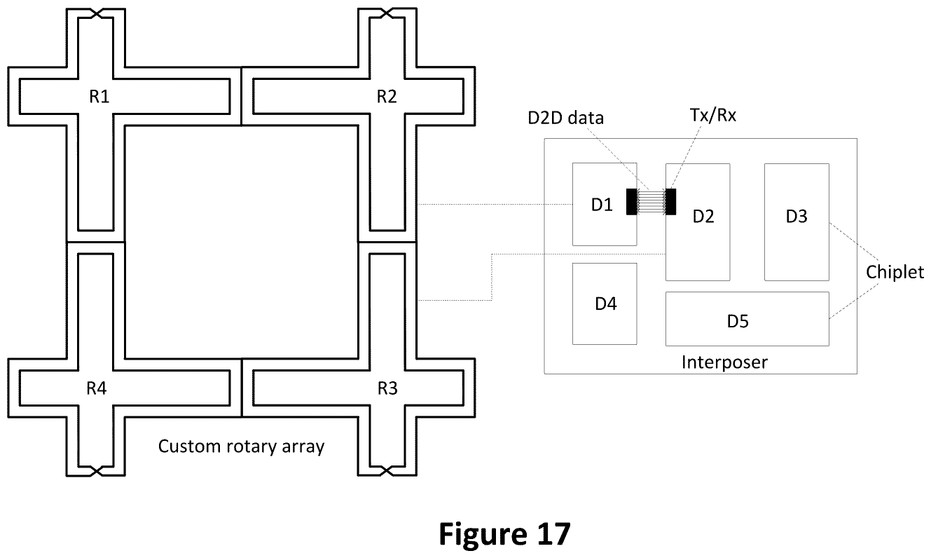

Further examples of custom rotary array schemes are depicted in FIGS. 15, 16, and 17 to demonstrate the applicability and usage of custom rings for D2D IOs. Note that, in each of these examples, the same phase points on multiple rings and/or different phase points with deterministic delays on the custom rings may be used for D2D IO. It will be apparent that many other designs of custom rotary oscillators and/or oscillator arrays may be used in accordance with various embodiments. Furthermore, resonant ring structures with different designs may be combined in a rotary oscillator array.

### D2D Communication Using Resonant Standing Wave Oscillators

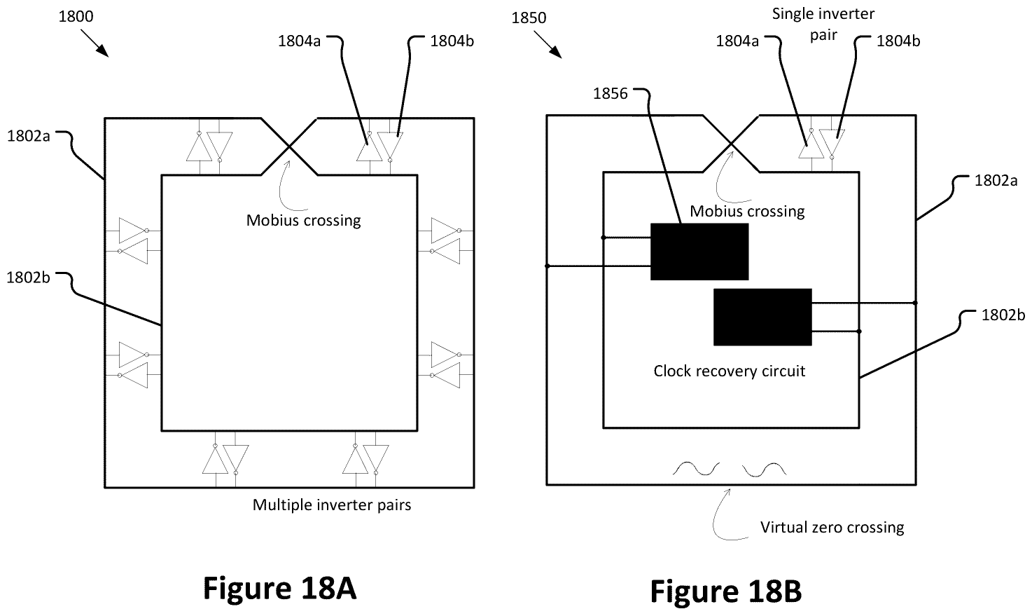

In a rotary traveling wave oscillator (RTWO), the clock signal continues to move in an uninterrupted fashion until it encounters another wave along the medium or until it encounters a boundary with another medium. For a RTWO, the distributed inverter pairs enable the multiple phases. Rotary traveling waves may be implemented using square rings and/or custom rings, as described herein. Both square and custom rings can be distributed using array structures as described herein. A sample RTWO 1800 with a square ring rotary structure is shown in FIG. 18A. The RTWO 1800 includes rotary rings 1802a-b coupled to one another via a mobius crossing, and multiple pairs of cross-coupled inverters 1804a-b coupled between the rotary rings 1802a-b.

In a standing wave (SW) scheme using transmission lines, each point on the transmission line generates a sine wave with different amplitude due to the parasitic losses. The ring-based standing wave clocking topology is motivated by the goal of combining the energy recycling feature of the rotary clock scheme with the constant phase (across all points in the ring) of the standing wave oscillator. The mobius termination back to the source is used where the standing wave ring is a single cross coupled rotary wave oscillator. A sample standing wave oscillator 1850 with a square ring standing wave structure is shown in FIG. 18B. The standing wave oscillator 1850 includes rotary rings 1852a-b coupled to one another via a mobius crossing, and a single pair of cross-coupled inverters 1854a-b coupled between the rotary rings 1852a-b. The standing wave oscillator 1850 may further include one or more clock recovery circuits 1856 coupled to the rings 1852a-b to generate an output clock based on the signals at the rings 1852a-b.

The implications of having the mobius connection at the cross coupled inverters location is that the ring's clock information is dual phased. A clock recovery circuit is used to obtain the required clock. Note that, due to the dual phased nature of the clock, the clock recovery circuits on one side needs to have their polarity reversed compared to the ones on the other side to enable same phase tapping. Equal and opposite phased waves will meet at the middle of this differential loop. A traveling wave originated due to wire losses will find its opposite wave at this middle and cancel the opposite wave.

In the RTWO structure, due to the propagation of the wave in one direction of the transmission line, the multiple-phase signals can be obtained from different positions on the transmission line. In case of a standing wave oscillator (SWO), the generated signals have the same phase and different amplitudes. Both the RTWO and SWO circuits have the same property of distributing high frequency clock with low skew and low jitter which can be used for global clocking.

Various embodiments herein may use standing wave oscillators for D2D IO. The standing wave oscillators may include rectangular (e.g., square or other rectangle) rings, and/or custom (e.g., rectilinear) rings. The oscillators may include interconnects and inverter pairs (e.g., on the chip and/or interposer) that are terminated mobiusly to generate a resonating clock signal. The embodiments may enable the use of resonant ring with standing wave clocks that can be employed for D2D IO in any multi-die system.

As discussed above with respect to the traveling wave oscillator embodiments, the ring structures may be implemented in the interposer (e.g., silicon interposer). The inverter pairs may be implemented in the dies that are coupled to the interposer and/or in the interposer itself. The ring oscillators may be stacked to form standing wave oscillator arrays to distribute the required clocks across the whole reticle. Embodiments may include a chiplet-aware resonant standing wave array implementation to identify the required clock tap-points for D2D IO.

One of the key properties of standing wave rings is that the clock phase is constant across the rings. However, the amplitude varies. A clock recovery circuit may be used to extract the square wave clock. The clocks can be tapped out of these structures with clock-recovery circuits and provided across dies which are used to serialize and de-serialize data. Thus, the standing wave rings enable constant phase clocks. Accordingly, the clock signals may be tapped from different convenient points (e.g., with inherent synchronization/phase alignment by construction) on the ring structures and provided as respective inputs to the dies (e.g., for D2D IO).

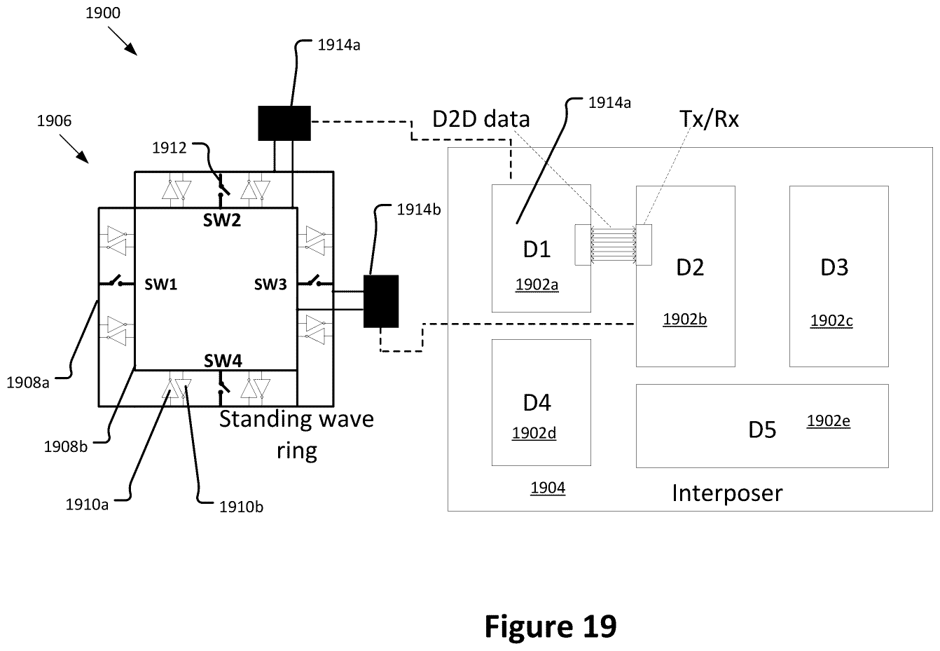

FIG. 19 illustrates an example multi-die system 1900 in accordance with various embodiments. The multi-die system 1900 may include a plurality of dies 1902a-e coupled to an interposer 1904. The multi-die system 1900 may further include a rotary oscillator 1906 that is operable in a standing wave mode. The rotary oscillator 1906 may include rings 1908a-b with pairs of cross-coupled inverters 1910a-b coupled between the rings 1908a-b. The rotary oscillator 1906 may further include one or more switches 1912 coupled between the rings 1908a-b. The switches 1912 may be implemented in the interposer and/or the top dic(s). In some embodiments, the rotary oscillator 1906 may be switchable between a standing wave mode and a traveling wave mode. In the traveling wave mode, all of the switches 1912 may be open. In the standing wave mode, one of the switches 1912 may be closed to short the inner ring and the outer ring together. The circuit may include any suitable number of one or more switches coupled between the inner ring and the outer ring, such as 4 rings as shown in FIG. 19 or another number of switches. In some embodiments, the rotary oscillator 1906 may only operate in the standing wave mode and not in the traveling wave mode. For example, one of the switches 1912 may be closed during operation.

The clock signals from the rotary oscillator 1906 may be provided to the dies 1902a-c. For example, FIG. 19 shows clock signals tapped from the rotary oscillator 1906 and provided to dies 1902a and 1902b via respective clock recovery circuits 1914a-b. The clock recover circuits 1914a-b may generate a square wave clock signal from the signals received rom the rings 1908a-b. By tapping off similar phase points and using that as IO clock for the nearest serializer/de-serializer, it enables the use of one high-speed clock period as the D2D transmission window. Note that, since high-speed clocks may be launched near die boundaries (where TX/RX PHY circuits reside), IO clocks may have to travel a little less than 2*Lᵢₑₙ (where Lᵢₑₙ is the length of the ring) within the chiplet.

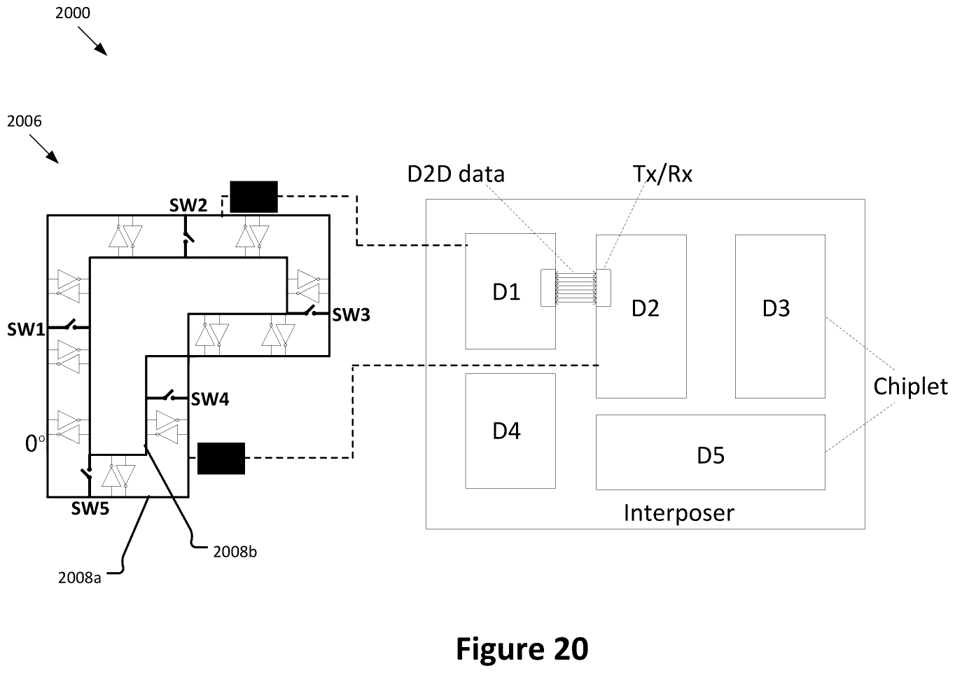

FIG. 20 illustrates another example multi-die system 2000 in accordance with various embodiments. The multi-die system 2000 is similar to the multi-die system 1900, except that the rotary oscillator 2006 includes custom (e.g., rectilinear and non-rectangular) rings 2008a-b. The properties of the oscillations remain similar to that of the regular square ring-based standing wave oscillator.

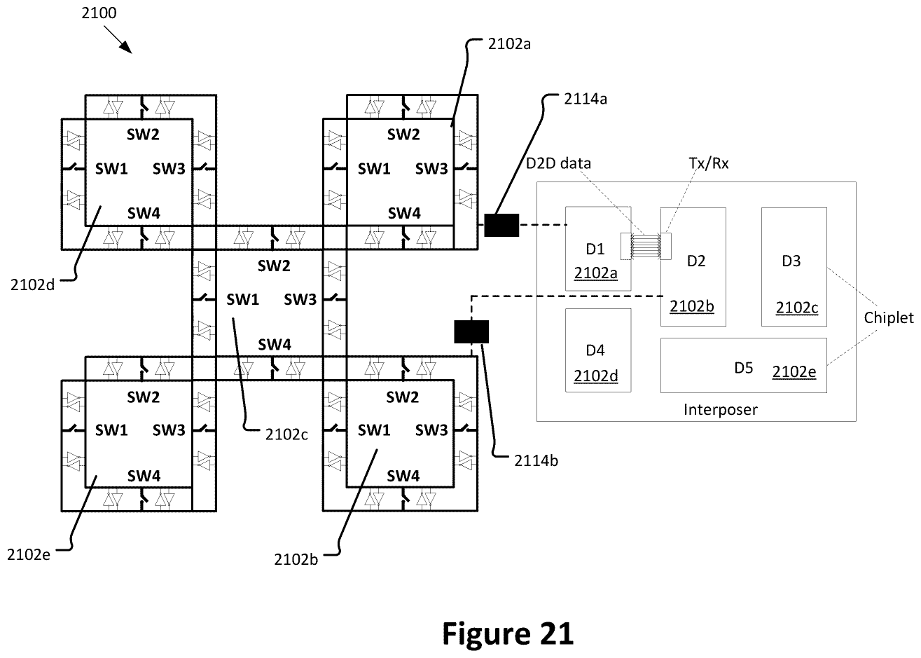

FIG. 21 illustrates another multi-die system 2100 in accordance with various embodiments. The multi-die system 2100 is similar to the multi-die system 1900, except that the multi-die system 2100 includes an array of oscillators 2106a-e coupled (e.g., shorted) to one another. The oscillators 2106a-e may be similar to the oscillator 1906 of FIG. 19. In other embodiments, the array may include different oscillator designs, such as one or more custom oscillators (e.g., oscillator 2006 and/or another type of custom oscillator). As the phases on the oscillators 2106a-e are the same, the clocks for different dies 2102a-e may be tapped from any same-phase points (through clock recovery circuits). For example, as shown in FIG. 21, die 2102a may receive a clock signal from oscillator 2106a via clock recovery circuit 2114a, and die 2102b may receive a clock signal from oscillator 2106b via clock recovery circuit 2114b.

Furthermore, the resonant rings may be implemented to enable a favorable transmit/receive window for D2D IO, e.g., depending on the architecture and/or placement of the dies 2102a-e. Thus, a chiplet-placement aware resonant rotary clocking scheme may be implemented on the interposer for efficient D2D IO. Note that, as discussed herein, this scheme may be extended to custom ring based standing wave oscillator arrays and other array topologies.

### Example System

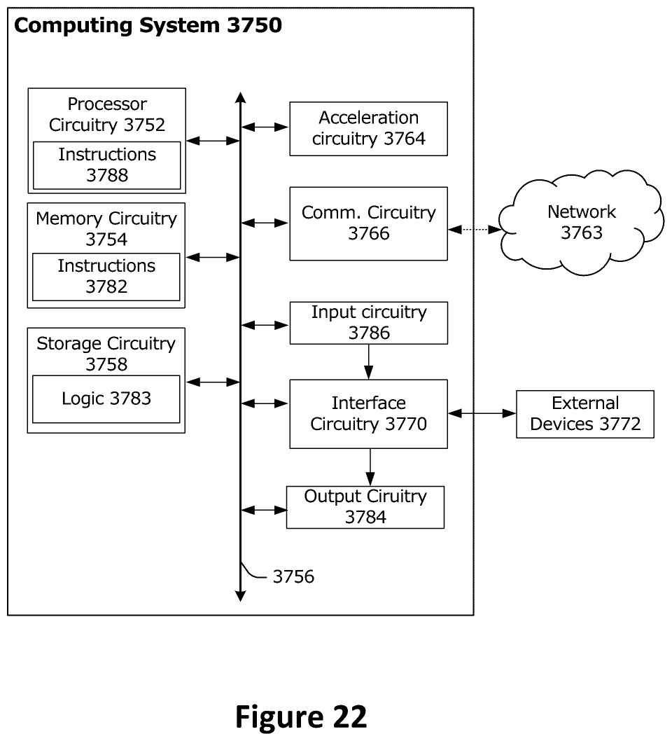

FIG. 22 illustrates an example of components that may be present in a computing system 3750 for implementing the techniques described herein. The computing system 3750 may include any combinations of the hardware or logical components referenced herein. The components may be implemented as ICs, portions thereof, discrete electronic devices, or other modules, instruction sets, programmable logic or algorithms, hardware, hardware accelerators, software, firmware, or a combination thereof adapted in the computing system 3750, or as components otherwise incorporated within a chassis of a larger system. For one embodiment, at least one processor 3752 may be packaged together with computational logic 3782 and configured to practice aspects of various example embodiments described herein to form a System in Package (SiP) or a System on Chip (SoC).

The system 3750 includes processor circuitry in the form of one or more processors 3752. The processor circuitry 3752 includes circuitry such as, but not limited to one or more processor cores and one or more of cache memory, low drop-out voltage regulators (LDOs), interrupt controllers, serial interfaces such as SPI, I2C or universal programmable serial interface circuit, real time clock (RTC), timer-counters including interval and watchdog timers, general purpose I/O, memory card controllers such as secure digital/multi-media card (SD/MMC) or similar, interfaces, mobile industry processor interface (MIPI) interfaces and Joint Test Access Group (JTAG) test access ports. In some implementations, the processor circuitry 3752 may include one or more hardware accelerators (e.g., same or similar to acceleration circuitry 3764), which may be microprocessors, programmable processing devices (e.g., FPGA, ASIC, etc.), or the like. The one or more accelerators may include, for example, computer vision and/or deep learning accelerators. In some implementations, the processor circuitry 3752 may include on-chip memory circuitry, which may include any suitable volatile and/or non-volatile memory, such as DRAM, SRAM, EPROM, EEPROM, Flash memory, solid-state memory, and/or any other type of memory device technology, such as those discussed herein.

The processor circuitry 3752 may include, for example, one or more processor cores (CPUs), application processors, GPUs, RISC processors, Acorn RISC Machine (ARM) processors, CISC processors, one or more DSPs, one or more FPGAs, one or more PLDs, one or more ASICs, one or more baseband processors, one or more radio-frequency integrated circuits (RFIC), one or more microprocessors or controllers, a multi-core processor, a multithreaded processor, an ultra-low voltage processor, an embedded processor, or any other known processing elements, or any suitable combination thereof. The processors (or cores) 3752 may be coupled with or may include memory/storage and may be configured to execute instructions stored in the memory/storage to enable various applications or operating systems to run on the platform 3750. The processors (or cores) 3752 is configured to operate application software to provide a specific service to a user of the platform 3750. In some embodiments, the processor(s) 3752 may be a special-purpose processor(s)/controller(s) configured (or configurable) to operate according to the various embodiments herein.

As examples, the processor(s) 3752 may include an Intel® Architecture Core™ based processor such as an i3, an i5, an i7, an i9 based processor; an Intel® microcontroller-based processor such as a Quark™, an Atom™, or other MCU-based processor; Pentium® processor(s), Xeon® processor(s), or another such processor available from Intel® Corporation, Santa Clara, California. However, any number other processors may be used, such as one or more of Advanced Micro Devices (AMD) Zen® Architecture such as Ryzen® or EPYC® processor(s), Accelerated Processing Units (APUs), MxGPUs, Epyc® processor(s), or the like; A5-A12 and/or S1-S4 processor(s) from Apple® Inc., Snapdragon™ or Centriq™ processor(s) from Qualcomm® Technologies, Inc., Texas Instruments, Inc.® Open Multimedia Applications Platform (OMAP)™ processor(s); a MIPS-based design from MIPS Technologies, Inc. such as MIPS Warrior M-class, Warrior I-class, and Warrior P-class processors; an ARM-based design licensed from ARM Holdings, Ltd., such as the ARM Cortex-A, Cortex-R, and Cortex-M family of processors; the ThunderX2® provided by Cavium™, Inc.; or the like.

In some implementations, the processor(s) 3752 and/or other components of the system 3750 may be a part of a system on a chip (SoC), System-in-Package (SiP), a multi-chip package (MCP), and/or the like, in which the processor(s) 3752 and other components are formed into a single integrated circuit, or a single package, such as the Edison™ or Galileo™ SoC boards from Intel® Corporation. Other examples of the processor(s) 3752 are mentioned elsewhere in the present disclosure. In embodiments, two or more components of the system 3750 may be on different dies that are coupled to a same base die. The base die may include resonant rings of a ROA, as described herein. The dies may tap the clock signal from the resonant rings at deterministic phase points, e.g., for D2D IO communication and/or other purposes.

The system 3750 may include or be coupled to acceleration circuitry 3764, which may be embodied by one or more artificial intelligence (AI)/machine learning (ML) accelerators, a neural compute stick, neuromorphic hardware, an FPGA, an arrangement of GPUs, one or more SoCs (including programmable SoCs), one or more CPUs, one or more digital signal processors, dedicated ASICs (including programmable ASICs), PLDs such as complex (CPLDs) or high complexity PLDs (HCPLDs), and/or other forms of specialized processors or circuitry designed to accomplish one or more specialized tasks. These tasks may include AI/ML processing (e.g., including training, inferencing, and classification operations), visual data processing, network data processing, object detection, rule analysis, or the like. In FPGA-based implementations, the acceleration circuitry 3764 may comprise logic blocks or logic fabric and other interconnected resources that may be programmed (configured) to perform various functions, such as the procedures, methods, functions, etc. of the various embodiments discussed herein. In such implementations, the acceleration circuitry 3764 may also include memory cells (e.g., EPROM, EEPROM, flash memory, static memory (e.g., SRAM, anti-fuses, etc.) used to store logic blocks, logic fabric, data, etc. in LUTs and the like.

In some implementations, the processor circuitry 3752 and/or acceleration circuitry 3764 may include hardware elements specifically tailored for machine learning and/or artificial intelligence (AI) functionality. In these implementations, the processor circuitry 3752 and/or acceleration circuitry 3764 may be, or may include, an AI engine chip that can run many different kinds of AI instruction sets once loaded with the appropriate weightings and training code. Additionally or alternatively, the processor circuitry 3752 and/or acceleration circuitry 3764 may be, or may include, AI accelerator(s), which may be one or more of the aforementioned hardware accelerators designed for hardware acceleration of AI applications. As examples, these processor(s) or accelerators may be a cluster of artificial intelligence (AI) GPUs, tensor processing units (TPUs) developed by Google® Inc., Real AI Processors (RAPS™) provided by AlphaICs®, Nervana™ Neural Network Processors (NNPs) provided by Intel® Corp., Intel® Movidius™ Myriad™ X Vision Processing Unit (VPU), NVIDIA® PX™ based GPUs, the NM500 chip provided by General Vision®, Hardware 3 provided by Tesla®, Inc., an Epiphany™ based processor provided by Adapteva®, or the like. In some embodiments, the processor circuitry 3752 and/or acceleration circuitry 3764 and/or hardware accelerator circuitry may be implemented as AI accelerating co-processor(s), such as the Hexagon 685 DSP provided by Qualcomm®, the PowerVR 2 NX Neural Net Accelerator (NNA) provided by Imagination Technologies Limited®, the Neural Engine core within the Apple® A11 or A12 Bionic SoC, the Neural Processing Unit (NPU) within the HiSilicon Kirin 3770 provided by Huawei®, and/or the like. In some hardware-based implementations, individual subsystems of system 3750 may be operated by the respective AI accelerating co-processor(s), AI GPUs, TPUs, or hardware accelerators (e.g., FPGAs, ASICs, DSPs, SoCs, etc.), etc., that are configured with appropriate logic blocks, bit stream(s), etc. to perform their respective functions.

The system 3750 also includes system memory 3754. Any number of memory devices may be used to provide for a given amount of system memory. As examples, the memory 3754 may be, or include, volatile memory such as random access memory (RAM), static RAM (SRAM), dynamic RAM (DRAM), synchronous DRAM (SDRAM), RAMBUS® Dynamic Random Access Memory (RDRAM®), and/or any other desired type of volatile memory device. Additionally or alternatively, the memory 3754 may be, or include, non-volatile memory such as read-only memory (ROM), erasable programmable ROM (EPROM), electrically erasable programmable (EEPROM), flash memory, non-volatile RAM, ferroelectric RAM, phase-change memory (PCM), flash memory, and/or any other desired type of non-volatile memory device. Access to the memory 3754 is controlled by a memory controller. The individual memory devices may be of any number of different package types such as single die package (SDP), dual die package (DDP) or quad die package (Q17P). Any number of other memory implementations may be used, such as dual inline memory modules (DIMMs) of different varieties including but not limited to microDIMMs or MiniDIMMs.

Storage circuitry 3758 provides persistent storage of information such as data, applications, operating systems and so forth. In an example, the storage 3758 may be implemented via a solid-state disk drive (SSDD) and/or high-speed electrically erasable memory (commonly referred to as “flash memory”). Other devices that may be used for the storage 3758 include flash memory cards, such as SD cards, microSD cards, XD picture cards, and the like, and USB flash drives. In an example, the memory device may be or may include memory devices that use chalcogenide glass, multi-threshold level NAND flash memory, NOR flash memory, single or multi-level Phase Change Memory (PCM), a resistive memory, nanowire memory, ferroelectric transistor random access memory (FeTRAM), anti-ferroelectric memory, magnetoresistive random access memory (MRAM) memory that incorporates memristor technology, phase change RAM (PRAM), resistive memory including the metal oxide base, the oxygen vacancy base and the conductive bridge Random Access Memory (CB-RAM), or spin transfer torque (STT)-MRAM, a spintronic magnetic junction memory based device, a magnetic tunneling junction (MTJ) based device, a Domain Wall (DW) and Spin Orbit Transfer (SOT) based device, a thyristor based memory device, a hard disk drive (HDD), micro HDD, of a combination thereof, and/or any other memory. The memory circuitry 3754 and/or storage circuitry 3758 may also incorporate three-dimensional (3D) cross-point (XPOINT) memories from Intel® and Micron®.

The memory circuitry 3754 and/or storage circuitry 3758 is/are configured to store computational logic 3783 in the form of software, firmware, microcode, or hardware-level instructions to implement the techniques described herein. The computational logic 3783 may be employed to store working copies and/or permanent copies of programming instructions, or data to create the programming instructions, for the operation of various components of system 3700 (e.g., drivers, libraries, application programming interfaces (APIs), etc.), an operating system of system 3700, one or more applications, and/or for carrying out the embodiments discussed herein. The computational logic 3783 may be stored or loaded into memory circuitry 3754 as instructions 3782, or data to create the instructions 3782, which are then accessed for execution by the processor circuitry 3752 to carry out the functions described herein. The processor circuitry 3752 and/or the acceleration circuitry 3764 accesses the memory circuitry 3754 and/or the storage circuitry 3758 over the interconnect (IX) 3756. The instructions 3782 direct the processor circuitry 3752 to perform a specific sequence or flow of actions, for example, as described with respect to flowchart(s) and block diagram(s) of operations and functionality depicted previously. The various elements may be implemented by assembler instructions supported by processor circuitry 3752 or high-level languages that may be compiled into instructions 3781, or data to create the instructions 3781, to be executed by the processor circuitry 3752. The permanent copy of the programming instructions may be placed into persistent storage devices of storage circuitry 3758 in the factory or in the field through, for example, a distribution medium (not shown), through a communication interface (e.g., from a distribution server (not shown)), over-the-air (OTA), or any combination thereof.

The IX 3756 couples the processor 3752 to communication circuitry 3766 for communications with other devices, such as a remote server (not shown) and the like. The communication circuitry 3766 is a hardware element, or collection of hardware elements, used to communicate over one or more networks 3763 and/or with other devices. In one example, communication circuitry 3766 is, or includes, transceiver circuitry configured to enable wireless communications using any number of frequencies and protocols such as, for example, the Institute of Electrical and Electronics Engineers (IEEE) 802.11 (and/or variants thereof), IEEE 802.7.4, Bluetooth® and/or Bluetooth® low energy (BLE), ZigBee®, LoRaWAN™ (Long Range Wide Area Network), a cellular protocol such as 3GPP LTE and/or Fifth Generation (5G)/New Radio (NR), and/or the like. Additionally or alternatively, communication circuitry 3766 is, or includes, one or more network interface controllers (NICs) to enable wired communication using, for example, an Ethernet connection, Controller Area Network (CAN), Local Interconnect Network (LIN), DeviceNet, ControlNet, Data Highway+, or PROFINET, among many others.

The IX 3756 also couples the processor 3752 to interface circuitry 3770 that is used to connect system 3750 with one or more external devices 3772. The external devices 3772 may include, for example, sensors, actuators, positioning circuitry (e.g., global navigation satellite system (GNSS)/Global Positioning System (GPS) circuitry), client devices, servers, network appliances (e.g., switches, hubs, routers, etc.), integrated photonics devices (e.g., optical neural network (ONN) integrated circuit (IC) and/or the like), and/or other like devices.

In some optional examples, various input/output (I/O) devices may be present within or connected to, the system 3750, which are referred to as input circuitry 3786 and output circuitry 3784 in FIG. 37. The input circuitry 3786 and output circuitry 3784 include one or more user interfaces designed to enable user interaction with the platform 3750 and/or peripheral component interfaces designed to enable peripheral component interaction with the platform 3750. Input circuitry 3786 may include any physical or virtual means for accepting an input including, inter alia, one or more physical or virtual buttons (e.g., a reset button), a physical keyboard, keypad, mouse, touchpad, touchscreen, microphones, scanner, headset, and/or the like. The output circuitry 3784 may be included to show information or otherwise convey information, such as sensor readings, actuator position(s), or other like information. Data and/or graphics may be displayed on one or more user interface components of the output circuitry 3784. Output circuitry 3784 may include any number and/or combinations of audio or visual display, including, inter alia, one or more simple visual outputs/indicators (e.g., binary status indicators (e.g., light emitting diodes (LEDs)) and multi-character visual outputs, or more complex outputs such as display devices or touchscreens (e.g., Liquid Crystal Displays (LCD), LED displays, quantum dot displays, projectors, etc.), with the output of characters, graphics, multimedia objects, and the like being generated or produced from the operation of the platform 3750. The output circuitry 3784 may also include speakers and/or other audio emitting devices, printer(s), and/or the like. Additionally or alternatively, sensor(s) may be used as the input circuitry 3784 (e.g., an image capture device, motion capture device, or the like) and one or more actuators may be used as the output device circuitry 3784 (e.g., an actuator to provide haptic feedback or the like). Peripheral component interfaces may include, but are not limited to, a non-volatile memory port, a USB port, an audio jack, a power supply interface, etc. In some embodiments, a display or console hardware, in the context of the present system, may be used to provide output and receive input of an edge computing system; to manage components or services of an edge computing system; identify a state of an edge computing component or service; or to conduct any other number of management or administration functions or service use cases.

The components of the system 3750 may communicate over the IX 3756. The IX 3756 may include any number of technologies, including ISA, extended ISA, 12C, SPI, point-to-point interfaces, power management bus (PMBus), PCI, PCIe, PCIx, Intel® UPI, Intel® Accelerator Link, Intel® CXL, CAPI, OpenCAPI, Intel® QPI, UPI, Intel® OPA IX, RapidIO™ system IXs, CCIX, Gen-Z Consortium IXs, a HyperTransport interconnect, NVLink provided by NVIDIA®, a Time-Trigger Protocol (TTP) system, a FlexRay system, PROFIBUS, and/or any number of other IX technologies. The IX 3756 may be a proprietary bus, for example, used in a SoC based system.

The number, capability, and/or capacity of the elements of system 3700 may vary, depending on whether computing system 3700 is used as a stationary computing device (e.g., a server computer in a data center, a workstation, a desktop computer, etc.) or a mobile computing device (e.g., a smartphone, tablet computing device, laptop computer, game console, IoT device, etc.). In various implementations, the computing device system 3700 may comprise one or more components of a data center, a desktop computer, a workstation, a laptop, a smartphone, a tablet, a digital camera, a smart appliance, a smart home hub, a network appliance, and/or any other device/system that processes data.

### EXAMPLES

Some non-limiting examples of various embodiments are provided below.

Example 1 is an comprising: a base die that includes resonant rings of respective rotary oscillators, wherein the resonant rings of different rotary oscillators are shorted to one another to form a rotary oscillator array (ROA); and a first die and a second die coupled to the base die, wherein the first die is to tap a clock signal from the ROA, and transmit the serialized data to the second die based on the tapped clock signal.

Example 2 may include the apparatus of example 1 or some other example herein, wherein the resonant rings of the respective rotary oscillators include a first ring and a second ring that are cross-coupled to one another, wherein the rotary oscillators further include one or more pairs of cross-coupled inverters that are coupled between the first ring and the second ring.

Example 3 may include the apparatus of example 2 or some other example herein, wherein the inverters are included in the base die.

Example 4 may include the apparatus of example 2 or some other example herein, wherein the inverters are included in at least one of the first die or the second die.

Example 5 may include the apparatus of example 4 or some other example herein, wherein the inverters are coupled to the resonant rings via micro-bumps.

Example 6 may include the apparatus of example 2-5 or some other example herein, wherein the rotary oscillators include a first rotary oscillator and a second rotary oscillator, wherein the first ring of the first rotary oscillator is shorted to the second ring of the second rotary oscillator and the second ring of the first rotary oscillator is shorted to the first ring of the second rotary oscillator.

Example 7 may include the apparatus of example 1-6 or some other example herein, wherein the clock signal is a first clock signal, and wherein the second die is to tap a second clock signal from the ROA, and receive the data based on the second clock signal.

Example 8 may include the apparatus of example 7 or some other example herein, wherein the first die includes transmit circuitry with one or more serializers to serialize the data based on the first clock signal for transmission to the second die, and wherein the second die includes receive circuitry with one or more deserializers to deserialize the data.

Example 9 may include the apparatus of example 7-8 or some other example herein, wherein the first clock signal has a same phase as the second clock signal.

Example 10 may include the apparatus of example 7-8 or some other example herein, wherein the first clock signal has a different phase than the second clock signal.

Example 11 may include the apparatus of example 10 or some other example herein, wherein the second clock signal is ahead in phase by 45 to 135 degrees compared to first the clock signal.

Example 12 may include the apparatus of example 7, 8, 10, or 11, wherein the data is transmitted via a communication bus with multiple channels that use respective pairs of tap points, wherein the respective pairs of tap points have different phase differences between the first and second clock signals.

Example 13 may include the apparatus of example 1-12 or some other example herein, wherein the rotary oscillators are rotary traveling wave oscillators.

Example 14 may include the apparatus of example 1-9 or some other example herein, wherein the rotary oscillators are rotary standing wave oscillators.

Example 15 may include the apparatus of example 1-14 or some other example herein, wherein at least one of the resonant rings has an irregular shape.

Example 16 may include the apparatus of example 15 or some other example herein, wherein the irregular shape is a non-rectangular rectilinear shape.

Example 17 may include the apparatus of example 1-16 or some other example herein, wherein at least one of the resonant rings has a rectangular shape.

Example 18 may include the apparatus of examples 1-17 or some other example herein, wherein at least one of the rotary oscillators is operable in a traveling wave mode and a standing wave mode.

Example 19 may include the apparatus of example 18 or some other example herein, wherein the rotary oscillators include one or more switches coupled between the first ring and the second ring of the respective rotary oscillators to control whether the respective rotary oscillators are in the traveling wave mode or the standing wave mode.

Example 20 may include the apparatus of claim 19 or some other example herein, wherein the switches are to be open when the respective rotary oscillator is in the traveling wave mode, and wherein a selected one of the switches is to be closed when the respective rotary oscillator is in the standing wave mode.

Example 21 may include the apparatus of claim 1-20 or some other example herein, wherein a first resonant ring of the resonant rings has a first long side below the first die and a second long side below the second die.

Example 22 may include the apparatus of claim 21, wherein the first resonant ring is rectangular and further includes a first short side coupled between the first and second long sides, and a second short side coupled between the first and second long sides.

Example 23 may include the apparatus of claim 21-22 or some other example herein, wherein the first long side is at least partially below a first D2D PHY circuitry of the first die, and wherein the second long side is at least partially below a second D2D PHY circuitry of the second die.

Example 24 may include the apparatus of claim 1-23 or some other example herein, wherein the rotary oscillators are standing wave oscillators, and wherein the rotary oscillators include one or more clock recovery circuits coupled to the resonant rings, wherein a first clock recovery circuit of the one or more clock recovery circuits is to generate the clock signal.

Example 25 may include the apparatus of example 24 or some other example herein, wherein the first clock recovery circuit is coupled to the first and second rings of the respective resonant rings.

Example 26 may include the apparatus of example 25, wherein the clock recovery circuits are to generate a square wave.

Example 27 may include a multi-die system comprising: a base die that includes resonant rings of respective rotary oscillators, wherein the resonant rings of different rotary oscillators are shorted to one another to form a rotary oscillator array (ROA); a first die that includes transmit circuitry to: tap a first clock signal from the ROA, serialize data based on the first clock signal, and transmit the serialized data to the second die via a communication bus; and a second die that includes receive circuitry to receive the serialized data via the communication bus, tap a second clock signal from the ROA, and deserialize the data based on the second clock signal.

Example 28 may include an apparatus comprising: a base die that includes a resonant ring structure of a rotary oscillator; a first die coupled to the base die, wherein the first die includes transmit circuitry above a resonant ring, wherein the transmit circuitry is to tap a first clock signal from the resonant ring and transmit the data based on the first clock signal; and a second die coupled to the base die, wherein the second die includes receive circuitry above the resonant ring, and wherein the second die includes receive circuitry to tap a second clock signal from the resonant ring and receive the data based on the second clock signal.

Example 29 may include the apparatus of example 28, wherein the transmit circuitry is above a first long edge of the resonant ring structure and is to tap the first clock signal from the first long edge, and wherein the receive circuitry is above a second long edge of the resonant ring structure and is to tap the second clock signal from the second long edge.

Example 30 may include the apparatus of example 28 or some other example herein, wherein the rotary oscillator is a rotary traveling wave oscillator.

Example 31 may include the apparatus of example 30 or some other example herein, wherein the first clock signal has a different phase than the second clock signal.

Example 32 may include the apparatus of example 31 or some other example herein, wherein the second clock signal is ahead in phase by 45 to 135 degrees compared to first the clock signal.

Example 33 may include the apparatus of example 28 or some other example herein, wherein the rotary oscillator is a rotary standing wave oscillator.

Example 34 may include the apparatus of example 33 or some other example herein, wherein the rotary oscillator further includes a clock recovery circuit coupled to a first ring and a second ring of the resonant ring structure to generate a square wave signal as the clock signal. Example 35 may include the apparatus of any of examples 28-34 or some other example herein, wherein the transmit circuitry includes one or more serializers to serialize the data based on the first clock signal, and wherein the receive circuitry includes one or more deserializers to deserialize the data based on the second clock signal.

Example 36 may include a computer system comprising: a multi-die system (MDS) and one or more antennas coupled to the MDS to enable the computer system to wirelessly communicate with another device. The MDS may include: a base die that includes a resonant ring structure of a traveling wave rotary oscillator (RTWO) array; a first die coupled to the base die, wherein the first die includes transmit circuitry, and wherein the transmit circuitry is to tap a first clock signal from the resonant ring and serialize data based on the first clock signal; and a second die coupled to the base die, wherein the second die includes receive circuitry above the resonant ring, wherein the receive circuitry is to tap a second clock signal from the resonant ring and deserialize the data based on the second clock signal, and wherein the second clock signal has a different phase than the first clock signal.

Example 37 may include the system of example 36, wherein the second clock signal is ahead in phase by 45 to 135 degrees compared to first the clock signal.

Example 38 may include the system of example 36 or 37, wherein the data is transmitted via a communication bus with multiple channels that use respective pairs of tap points, wherein the respective pairs of tap points have different phase differences between the respective first and second clock signals.

Example 39 may include the system of example 36-38, wherein the transmit circuitry and the receive circuitry are to tap the respective first and second clock signals from a same ring of the resonant ring structure.

Example 40 may include the system of example 36-38, wherein the transmit circuitry and the receive circuitry are to tap the respective first and second clock signals from different rings of the resonant ring structure.

Example 41 may include a computer system comprising: the apparatus of any one of examples 1-40; and at least one of a memory, a communication interface, a radio frequency circuit, or one or more antennas couple to the multi-die system.

Although certain embodiments have been illustrated and described herein for purposes of description, this application is intended to cover any adaptations or variations of the embodiments discussed herein. Therefore, it is manifestly intended that embodiments described herein be limited only by the claims.

Where the disclosure recites “a” or “a first” element or the equivalent thereof, such disclosure includes one or more such elements, neither requiring nor excluding two or more such elements. Further, ordinal indicators (e.g., first, second, or third) for identified elements are used to distinguish between the elements, and do not indicate or imply a required or limited number of such elements, nor do they indicate a particular position or order of such elements unless otherwise specifically stated.

What is claimed is:

1. An apparatus comprising:
a base die that includes resonant rings of respective rotary oscillators, wherein the resonant rings of different rotary oscillators are shorted to one another to form a rotary oscillator array (ROA); and
a first die and a second die coupled to the base die, wherein the first die is to tap a first clock signal from the ROA and transmit data to the second die based on the first clock signal; and wherein the second die is to tap a second clock signal from the ROA, and receive the data based on the second clock signal.

2. The apparatus of claim 1, wherein the resonant rings of the respective rotary oscillators include a first ring and a second ring that are cross-coupled to one another, wherein the rotary oscillators further include one or more pairs of cross-coupled inverters that are coupled between the first ring and the second ring.

3. The apparatus of claim 1, wherein the first clock signal has a same phase as the second clock signal.

4. The apparatus of claim 1, wherein the rotary oscillators are rotary traveling wave oscillators.

5. The apparatus of claim 1, wherein the second clock signal is ahead in phase by 45 to 135 degrees compared to the first clock signal.

6. The apparatus of claim 5, wherein the data is transmitted via a communication bus with multiple channels that use respective pairs of tap points, wherein the respective pairs of tap points have different phase differences between the first and second clock signals.

7. The apparatus of claim 1, wherein the rotary oscillators are rotary standing wave oscillators.

8. The apparatus of claim 1, wherein at least one of the rotary oscillators is operable in a traveling wave mode and a standing wave mode, and wherein the rotary oscillators include one or more switches coupled between the first ring and the second ring of the respective rotary oscillators, and wherein the apparatus further comprises control circuitry to control the switches to be open when the respective rotary oscillator is in the traveling wave mode, and control the switches to have a selected one of the switches to be closed when the respective rotary oscillator is in the standing wave mode.

9. The apparatus of claim 1, wherein the first die includes one or more serializers to serialize the data for transmission based on the first clock signal, and wherein the second die includes one or more deserializers to deserialize the data.

10. An apparatus comprising:
a base die that includes a resonant ring structure of a rotary oscillator;
a first die coupled to the base die, wherein the first die includes transmit circuitry above a resonant ring, wherein the transmit circuitry is to tap a first clock signal from the resonant ring, and transmit the data over a communication bus based on the first clock signal; and
a second die coupled to the base die, wherein the second die includes receive circuitry above the resonant ring and coupled to the communication bus, wherein the second die is to tap a second clock signal from the resonant ring, and receive the data based on the second clock signal.

11. The apparatus of claim 10, wherein the transmit circuitry is above a first long edge of the resonant ring structure and is to tap the first clock signal from the first long edge, and wherein the receive circuitry is above a second long edge of the resonant ring structure and is to tap the second clock signal from the second long edge.

12. The apparatus of claim 10, wherein the rotary oscillator is a rotary traveling wave oscillator.

13. The apparatus of claim 12, wherein the rotary oscillator further includes a clock recovery circuit coupled to a first ring and a second ring of the resonant ring structure to generate a square wave signal as the clock signal.

14. The apparatus of claim 10, wherein the second clock signal is ahead in phase by 45 to 135 degrees compared to the first clock signal.

15. The apparatus of claim 14, wherein the transmit circuitry includes one or more serializers to serialize the data, based on the first clock signal, for transmission over the communication bus, and wherein the receive circuitry includes one or more deserializers to deserialize the data based on the second clock signal.

16. A computer system, comprising:
a multi-die system (MDS) that includes:
a base die that includes a resonant ring structure of a traveling wave rotary oscillator (RTWO) array,
a first die coupled to the base die, wherein the first die includes transmit circuitry, and wherein the transmit circuitry is to tap a first clock signal from the resonant ring structure and serialize data based on the first clock signal, and
a second die coupled to the base die, wherein the second die includes receive circuitry, wherein the receive circuitry is to tap a second clock signal from the resonant ring structure and deserialize the data based on the second clock signal, and wherein the second clock signal has a different phase than the first clock signal; and
one or more memory modules coupled to the first die.

17. The system of claim 16, wherein the data is transmitted via a communication bus with multiple channels that use respective pairs of tap points, wherein the respective pairs of tap points have different phase differences between the respective first and second clock signals.

18. The system of claim 16, wherein the transmit circuitry and the receive circuitry are to tap the respective first and second clock signals from a same ring of the resonant ring structure.

19. The system of claim 16, wherein the transmit circuitry and the receive circuitry are to tap the respective first and second clock signals from different rings of the resonant ring structure.

20. The system of claim 16, wherein the transmit circuitry is above a first long edge of the resonant ring structure and is to tap the first clock signal from the first long edge, and wherein the receive circuitry is above a second long edge of the resonant ring structure and is to tap the second clock signal from the second long edge.
